(19) United States
(12) Patent Application Publication
(10) Pub. No.: US 2022/0344209 A1
(43) Pub. Date: Oct. 27, 2022

(54) HIGH DENSITY 3D ROUTING WITH ROTATIONAL SYMMETRY FOR A PLURALITY OF 3D DEVICES

(71) Applicant: Tokyo Electron Limited, Tokyo (JP)

(72) Inventors: H. Jim Fulford, Albany, NY (US); Mark I. Gardner, Albany, NY (US); Partha Mukhopadhyay, Albany, NY (US)

(73) Assignee: Tokyo Electron Limited, Tokyo (JP)

(21) Appl. No.: 17/718,196

(22) Filed: Apr. 11, 2022

Related U.S. Application Data
(60) Provisional application No. 63/180,435, filed on Apr. 27, 2021.

(51) Int. Cl. H01L 21/822; H01L 27/06; H01L 27/092; H01L 21/8238

(52) U.S. Cl. CPC H01L 21/8221; H01L 27/0688; H01L 27/092; H01L 21/823885; H01L 21/823871

(57) ABSTRACT

Semiconductor devices and corresponding methods of manufacture are disclosed. The method includes forming vertical channel structures on a substrate. The vertical channel structures are formed within a layer stack of alternating layers of a first metal and a first dielectric. The vertical channel structures are channels of field effect transistors that have a current flow path perpendicular to a surface of the substrate. The vertical channel structures have a dielectric core. The method includes forming openings on the substrate that uncover a region of the layer stack adjacent to the vertical channel structures. The method includes, for each vertical channel structure, forming a corresponding staircase region in the layer stack, and forming metal contacts within each staircase region.

### CROSS-REFERENCE TO RELATED APPLICATIONS

The present application claims the benefit of and priority to U.S. Provisional Patent Application No. 63/180,435, filed Apr. 27, 2021, and entitled “High Density 3D Routing with Rotational Symmetry for a Plurality of 3D Devices,” the contents of which is incorporated by reference in its entirety for all purposes.

### FIELD OF THE DISCLOSURE

This disclosure relates to microelectronic devices including semiconductor devices, transistors, and integrated circuits, including methods of microfabrication.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate. Historically, with microfabrication, transistors have been created in one plane, with wiring or metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Three-dimensional integration (e.g. the vertical stacking of multiple devices) aims to overcome scaling limitations experienced in planar devices by increasing transistor density in volume rather than area. Three-dimensional integration as applied to random logic designs is substantially more difficult than alternative approaches. Three-dimensional integration for logic chips (e.g., CPU (central processing unit), GPU (graphics processing unit), FPGA (field programmable gate array, SoC (System on a Chip), etc.) are being pursued.

The techniques described herein include methods and devices for 3D fabrication of semiconductor devices. Specifically, techniques may include self-aligned metal routing for vertical channel transistors achieved with 360 degree symmetry for 3D vertical transistors. Excellent compact circuit layout may be obtained with such techniques. Techniques herein can be used for any geometry device (i.e. circular, rectangular, ellipse).

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

At least one aspect of the present disclosure is directed to a method for microfabrication. The method includes forming vertical channel structures on a substrate. The vertical channel structures can be formed within a layer stack of alternating layers of a first metal and a first dielectric. The vertical channel structures can have a current flow path perpendicular to a surface of the substrate. The vertical channel structures can have a dielectric core. The method includes forming openings on the substrate that uncover a region of the layer stack adjacent to the vertical channel structures. The method includes, for each vertical channel structure, forming a corresponding staircase region in the layer stack in plane with a corresponding vertical channel structure. The staircase region can have a staircase profile of metal layers in that each metal layer extending from the corresponding vertical channel structure has a different lateral length for different lateral access from above. The method includes forming metal contacts within the staircase region. Each metal contact can extend from a top surface of the substrate vertically into the staircase region to a corresponding metal line providing electrical connection to a corresponding vertical channel structure.

A given staircase region may be positioned between two vertical channel structures. The method may further include isolating the layers of metal lines between the two vertical channel structure stacks within the given staircase region. Isolating the layers of metal lines between the two vertical channel structures may include etching a ring structure around each vertical channel structure stack. The method may further include forming a second dielectric in the staircase region formed for each vertical channel structure.

The metal contacts may be formed to be electrically isolated from each other by the second dielectric. Forming the corresponding staircase region for each vertical channel structure may include performing at least two etch processes to different depths. The vertical channel structures may comprise a first field effect transistor and a second field effect transistor on top of the first field effect transistor. The first field effect transistor may be an n-type transistor structure and the second field effect transistor may be a p-type transistor structure. The staircase region may be a first staircase region for the first field effect transistor, and the method may include forming a second staircase region for the second field effect transistor.

At least one aspect of the present disclosure is directed to a method for microfabrication. The method may include forming vertical channel structures on a substrate. The vertical channel structures are formed within a layer stack of alternating layers of a first metal and a first dielectric. The vertical channel structures have a current flow path perpendicular to a surface of the substrate. The vertical channel structures have a dielectric core. The method includes forming slot-shaped openings on the substrate that uncover a region of the layer stack adjacent to the vertical channel structures. Each slot-shaped opening extends at a particular radial direction from a center point of the vertical channel structures. The method includes, for each vertical channel structure, forming a corresponding staircase region in the layer stack in plane with a corresponding vertical channel structure. The staircase region has a staircase profile of metal layers in that each metal layer extending from the corresponding vertical channel structure has a different lateral length for different lateral access from top down access. The method includes forming metal contacts within staircase region. Each metal contact extends from a top surface of the substrate vertically into the staircase region to a corresponding metal line providing electrical connection to a corresponding vertical channel transistor.

The method may further include etching a ring structure around each vertical channel structure stack. The method may further include forming a second dielectric in the staircase region formed for each vertical channel structure. The metal contacts may be formed to be electrically isolated from each other by the second dielectric. Forming the corresponding staircase region for each vertical channel structure may include performing at least two etch processes to different depths. The vertical channel structures may comprise a first field effect transistor and a second field effect transistor on top of the first field effect transistor. The first field effect transistor may be an n-type transistor structure and the second field effect transistor may be a p-type transistor structure.

Yet another aspect of the present disclosure is directed to a device. The device includes a stack of alternating layers of a metal and a dielectric on a substrate. The device includes a transistor structure in the stack and having a current flow path perpendicular to a surface of the substrate. The device includes a staircase region in the stack of alternating layers in-plane with the transistor structure. The staircase region extends through a plurality of metal layers in the stack that each extend from the transistor structure. The device includes a respective plurality of metal contacts coupled to the plurality of metal layers exposed in the staircase region. Each of the respective plurality of metal contacts extends vertically from a top surface of a respective metal layer of the plurality of metal layers to a corresponding metal line and provides electrical connection to the transistor structure.

The device may include a second dielectric in the staircase region that isolates the respective plurality of metal contacts are formed to be electrically isolated from each other by the second dielectric. At least one metal contact of the respective plurality of metal contacts may be electrically isolated from the transistor structure by the second dielectric. The device may include a second staircase region in the stack of alternating layers that is electrically coupled to a second transistor structure.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-19 show various views of a first process flow to manufacture semiconductor devices with rotational symmetry, according to an embodiment;

FIGS. 20-36 show various views of a second process flow to manufacture semiconductor devices with rotational symmetry, according to an embodiment;

FIGS. 37-49 show various views of a first process flow to manufacture semiconductor devices with rotational symmetry, according to an embodiment; and

FIGS. 50 and 51 show a flow diagrams of example methods for microfabrication using the process flows described in connection with FIGS. 1-49, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Techniques herein include methods and devices for 3D fabrication of semiconductor devices. Specifically, techniques include self-aligned metal routing for vertical channel transistors achieved with 360-degree symmetry for 3D vertical transistors. Excellent compact circuit layout is obtained with such techniques. Techniques herein can be used for any geometry device (e.g., circular, rectangular, ellipse, etc.). As used herein, the value N refers to the number of alternating layers of metal and dielectric are utilized to form various transistor devices. For example, some embodiments herein show an N=8 3D stack, but techniques apply to any number of N layers for any number of stacked devices, which may be connected with 3D wiring or metallization. Accordingly, high density circuit formation is enabled because devices are grown, or otherwise formed, vertically. Embodiments also include self-aligned contained cap layer etching techniques to greatly increase circuit routing density.

One advantage with techniques herein is enabling higher density circuits to be produced at reduced cost. The methods described herein provide an efficient 3D process flow that reduces masking steps with our invention with precise control of the vertical silicon channel thickness and 3D isolation. Devices include vertical channel transistors with metal self-aligned to 3D source gate and drain on any semiconductor substrate for any number of vertical devices. Self-aligned dielectrics used herein as well as integrated hard mask etching enable creating openings for different metal contacts for drain, gate and source without any lithography.

One embodiment described herein includes a p-n device fabrication and cap layer etching technique for routing. Figures herein illustrate a 3D stack N=4 devices. Another embodiment includes n-n-p device fabrication and cap layer etching techniques for routing. Figures show an example of N=6 devices, any N device 3D stack can be used herein. Other embodiments include self-aligned contained cap layer etching techniques, as well as process flow and layout.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections, and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

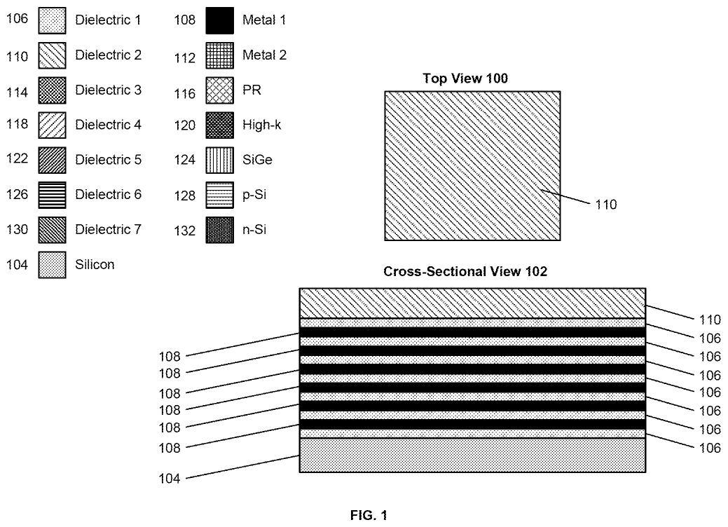

FIGS. 1-19 show various views of a first process flow to manufacture semiconductor devices with rotational symmetry. Each of the FIGS. 1-19 generally refer to one or more process steps in a process flow, each of which are described in detail in connection with a respective Figure. For the purposes of simplicity and ease of visualization, some reference numbers may be omitted from some Figures.

FIG. 1 illustrates a top view 100 and a cross-sectional view 102 of a base structure (shown here as a stack of layers, however, any base structure can be used in connection with the techniques described herein). The layer stack is prepared of alternating layers of the first metal material 108 (shown in the legend as “Metal 1”) and the first dielectric material 106 (shown in the legend as “Dielectric 1”). The layers of the metal material 108 may be the same metal material, or in some implementations may be different materials. Likewise, the layers of the dielectric material 106 may be the same dielectric material, or may be constructed from different dielectric materials. Different materials can be used, but subsequent etching is simplified with layers in the stack alternating between two materials. The layer stack can be formed on a substrate 104 (shown in the legend as “Silicon 104”), which may be formed from silicon or other material.

In this example, a layer of the first dielectric material 106 is deposited on the substrate 104, and then six pairs of the first metal material 108 and the first dielectric material 106 are deposited. Then, a capping layer or top layer of a second dielectric material 110 (shown in the legend as “Dielectric 2”) is deposited. The capping layer can be relatively thicker, and can be a hardmask materials such as TiN. The first and second dielectric materials 106 and 110 are can be selected to have different etch resistivities. That is, a given dielectric material can be etched without etching other dielectric materials. The layers in the layer stack may be formed using any suitable material deposition technique, including atomic layer deposition (ALD), chemical vapor deposition (CVD), physical vapor deposition (PVD), plasma-enhanced CVD (PECVD), or epitaxial growth or deposition techniques. The first metal material 108 may be any type of conductive metal material, including copper, gold, silver, platinum, or other suitable materials. The first and second dielectric materials 108 may be any material with a relatively large dielectric constant, and may include oxide materials.

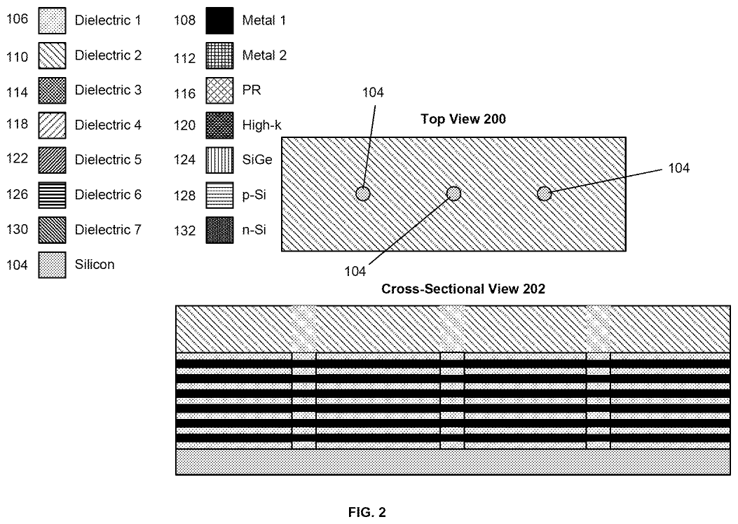

FIG. 2 illustrates a top view 200 and a cross-sectional view 202 of the next stage in the process flow. At this stage in the process flow, an etch mask is formed and used to directionally etch openings through the layer stack until uncovering the substrate 104 (or another underlying layer). Any suitable etching or material removal technique can be used, including but not limited to dry etching, wet etching, or plasma etching techniques, among others. The etch mask may be removed after the etching process is complete. The etching process may have an etch stop at the substrate 104. As shown, the etching process exposes the alternating layers of the first metal material 108 and the first dielectric material 106 in the openings.

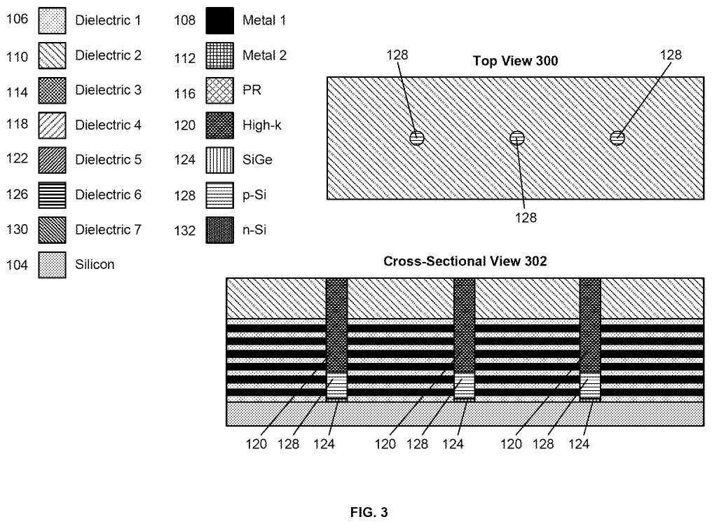

FIG. 3 illustrates a top view 300 and a cross-sectional view 302 of the next stage in the process flow. Vertical channel materials (e.g., the semiconductive-behaving material 128 or the second semiconductive-behaving material 130, etc.) can then be grown epitaxially with the uncovered substrate 104 as a seed material. To do so, in this stage in the process flow, a layer of a sacrificial material 124 (shown in the legend as “SiGe”) can first be grown in the openings formed in the previous process step. The sacrificial material 124 may be any type of material that can be epitaxially grown on the substrate layer 104, such as SiGe. The sacrificial material 124 may be formed using any suitable material formation technique, including epitaxial growth.

After forming the sacrificial material 124, the semiconductive-behaving material 128 (shown as “p-Si” in the legend) can be formed in the opening utilizing the sacrificial material 124 as a seed layer. The semiconductive-behaving material 128 can be formed to a predetermined height, for example, to just below the second layer of the first metal material 108 in the layer stack. Then, a thin layer of the high-k dielectric material 120 (shown in the legend as “High-k”) can be deposited conformally, for example, using an ALD technique. The high-k dielectric material 120 can then etched directionally, exposing the top of the semiconductive-behaving material 128. The high-k dielectric material 120 can be in contact with the second layer of the metal material 108, which will form a gate contact. After the high-k dielectric material 120 is deposited to cover the desired metal layer, the formation of the semiconductive-behaving material can continue, as shown. As shown, the semiconductive-behaving material 128 formation causes the semiconductive-behaving material 128 to grown in contact with the layer of the high-k dielectric material 120. The semiconductive-behaving material 128 can be grown to a second predetermined height, for example, just below the third layer of the metal material 108. Then, a portion of the high-k dielectric material 120 can be isotropically removed using a suitable etching technique, so as not to cover the third layer of the metal material 108.

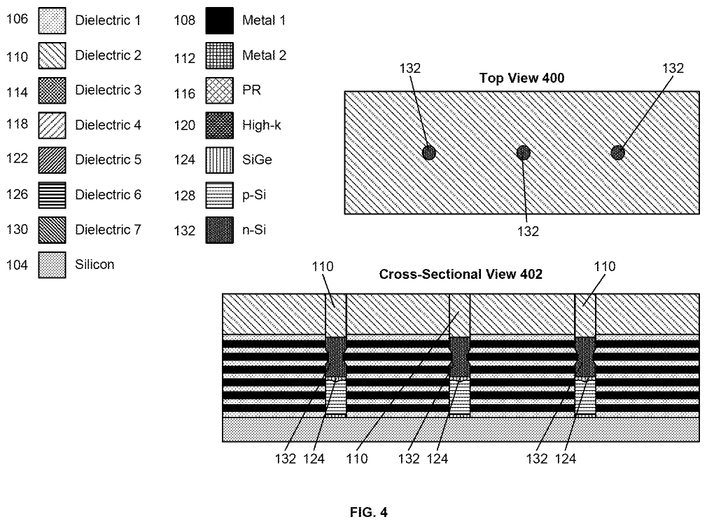

FIG. 4 illustrates a top view 400 and a cross-sectional view 402 of the next stage in the process flow. At this stage in the process flow, vertical formation (e.g., growth) of the semiconductive-behaving material 108 can continue after isotropically removing the portion of the high-k dielectric material 120. A given vertical channel structure can be formed from the semiconductive-behaving material 128 at a completed height, for example, after growing just beyond three layers of the metal material 108. Then, a second layer of the sacrificial material 124 can be grown to separate the semiconductive-behaving material 128 from a second semiconductive-behaving material 132 (shown in the legend as “n-Si”). A second vertical channel structure can be formed by growing a second channel structure of the second semiconductive-behaving material 132 using techniques similar to those described herein above. A second gate dielectric can be formed by using the techniques described above to form a layer of the high-k dielectric material 120 on a corresponding gate layer within the opening. The second semiconductive-behaving material 132 may be a doped silicon material, and may be similar to the semiconductive-behaving material 128. For example, the semiconductive-behaving material 128 can be a p-doped silicon, and the second semiconductive-behaving material 132 can be an n-doped silicon. As shown, each of the channels formed from the semiconductive-behaving material 128 and the second semiconductive-behaving material 132 are coupled to three respective layers of the metal material 108, which form two respective source/drain contacts and one respective gate contact (which is separated from the semiconductive-behaving material 128 or the second semiconductive-behaving material 132 by a layer of the high-k dielectric material 120).

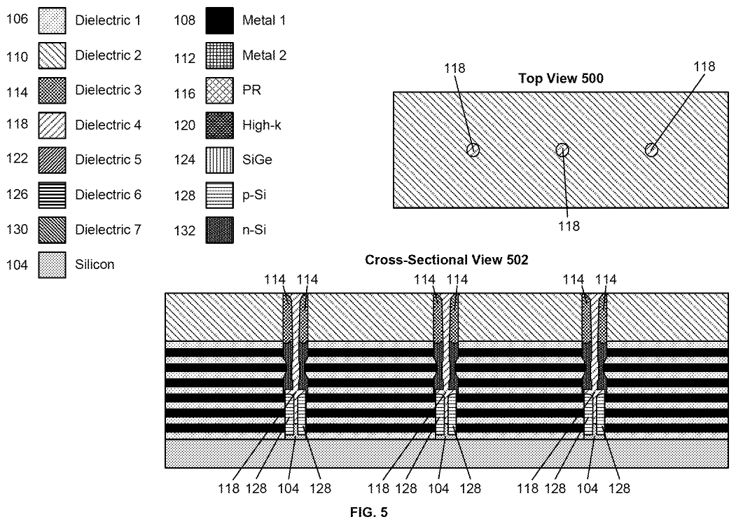

FIG. 5 illustrates a top view 500 and a cross-sectional view 502 of the next stage in the process flow. At this stage in the process flow, a core region of the vertical channel structures can be removed by directional etching. Masking for this etching process can accomplished by material deposition. An ALD can first be performed to deposit a layer of a third dielectric material 114 (shown in the legend as “Dielectric 3”) in the opening above the second semiconductive-behaving material 132. This can be a conformal deposition process with a generally equal thickness on all surfaces with precise control of thickness. Accordingly, this ALD film can be deposited on sidewalls of the openings without completely filling the openings. Then, a directional etching process is executed to remove a thickness of the ALD film sufficient to remove the film from horizontal surfaces. This removes the third dielectric material 114 from a central portion of the top of the vertical channel structures, while also removing the central portions of the semiconductive-behaving material 128, the second semiconductive-behaving material 132, and the layers of the sacrificial material 124, as shown. This forms a core opening through each device that is self-aligned by the ALD-deposited layer of the third dielectric material 114. The etching process can have an etch stop at the substrate 140. Then, an isotropic etching process, such as a vapor-phase etching process, can be used to fully remove the sacrificial material 124 so that channel structures are separated from each other. Then, a fourth dielectric material 118 (shown in the legend as “Dielectric 4”) can be formed to fill the core opening and the space previously occupied by the sacrificial material 124. Any overburden can be removed by a chemical-mechanical planarization (CMP) process.

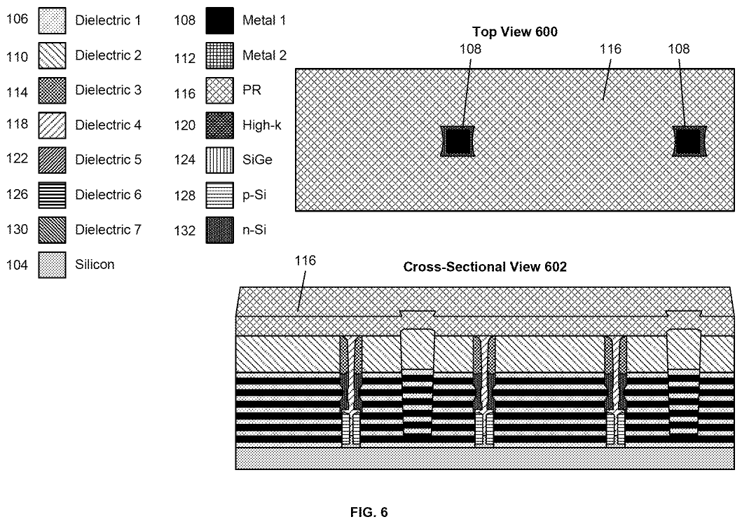

FIG. 6 illustrates a top view 600 and a cross-sectional view 602 of the next stage in the process flow. At this stage in the process flow, masking for transistor structure contacts is performed. As shown, a layer of a mask material 116 (shown in the legend as “PR,” and sometimes referred to herein as a “photoresist”) is formed on the top of the stack of layers including the devices formed in previous process steps. The mask material 116 can be patterned to have openings that will correspond to the transistor structure formed using the semiconductive-behaving material 128. Then, directional etching of the second dielectric material 110, the first dielectric material 106, and five layer-pairs of the first metal material 108 and the first dielectric material 106 can be performed. As shown, this forms openings that expose the bottom-most layer of the metal material 108 (e.g., a source/drain contact), which is coupled to the semiconductive-behaving material 128. Any suitable etching or material removal technique can be used, including but not limited to dry etching, wet etching, or plasma etching techniques, among others.

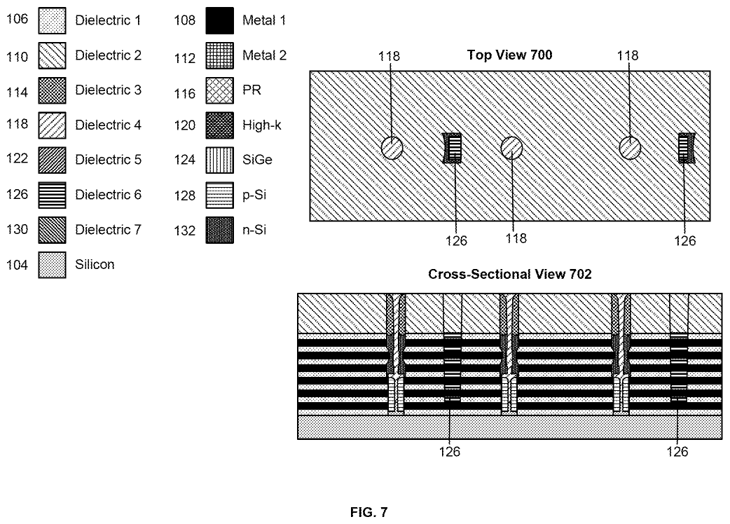

FIG. 7 illustrates a top view 700 and a cross-sectional view 702 of the next stage in the process flow. At this stage in the process flow, the mask material 116 is removed. Then, a selective deposition process (e.g., any suitable selective deposition technique, including ALD, CVD, PVD, etc.) is performed to form a fifth dielectric material 126 (shown as “Dielectric 6” in the legend) on the exposed surfaces of the metal material 108 within the openings formed in the previous process steps. As shown, this covers the layers of the metal material 108 in the openings with the fifth dielectric material 126. The fifth dielectric material 126 can protect the layers of the metal material 108 in subsequent etching steps (e.g., when forming the staircase region).

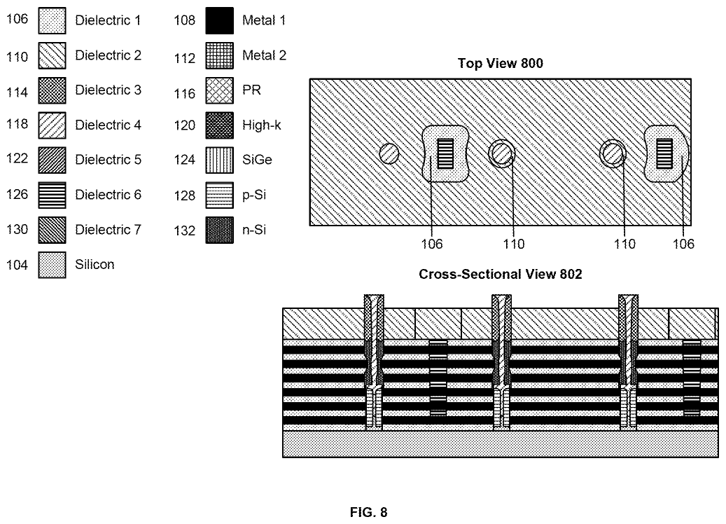

FIG. 8 illustrates a top view 800 and a cross-sectional view 802 of the next stage in the process flow. At this stage in the process flow, an isotropic etch of the second dielectric material 110 is performed. As shown, this etches the second dielectric material 110 both vertically and horizontally for a self-aligned contact opening. The second dielectric material 106 can be etched using any suitable etching or material removal technique, including but not limited to dry etching, wet etching, or plasma etching techniques, among others. The second dielectric material 110 can be etched in a predetermined patterned, such as the pattern shown in the top view 800. The top layer of the first dielectric material 106 can be an etch stop for this etching process. As shown, the opening in the second dielectric material 110 is formed around the openings formed in prior process steps, such that the previously-formed opening are centered at the openings formed in this stage of the process flow.

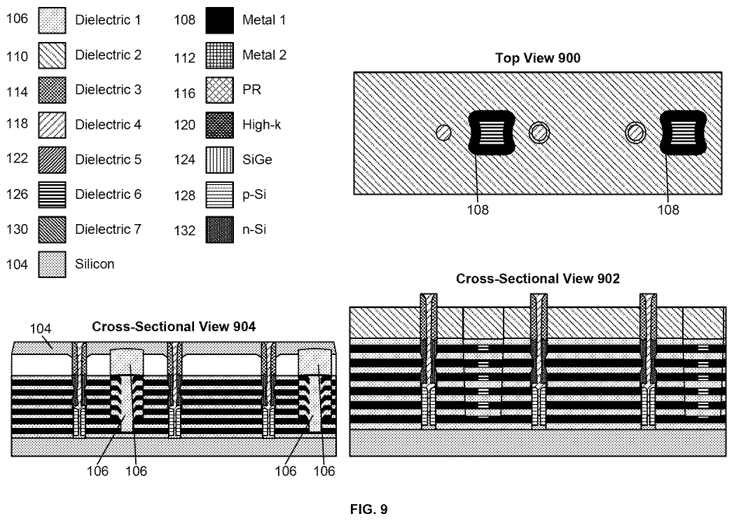

FIG. 9 illustrates a top view 900 and a cross-sectional view 902 of the next stage in the process flow. At this stage in the process flow, a directional etching step is performed to etch four layer-pairs of the first metal material 108 and the first dielectric material 106. As shown, this etching process can extend the openings in the second dielectric material 110 formed in the previous process step. This exposes the layer of the metal material 108 that corresponds to the gate electrode of the bottom transistor structure formed using the semiconductive-behaving material 128. This etching process forms a first “step” of a staircase region, with the bottom step corresponding to the bottom layer of the metal material 108. As shown, the sidewalls of the layers of the metal material 108 are exposed in the openings formed in this process stage.

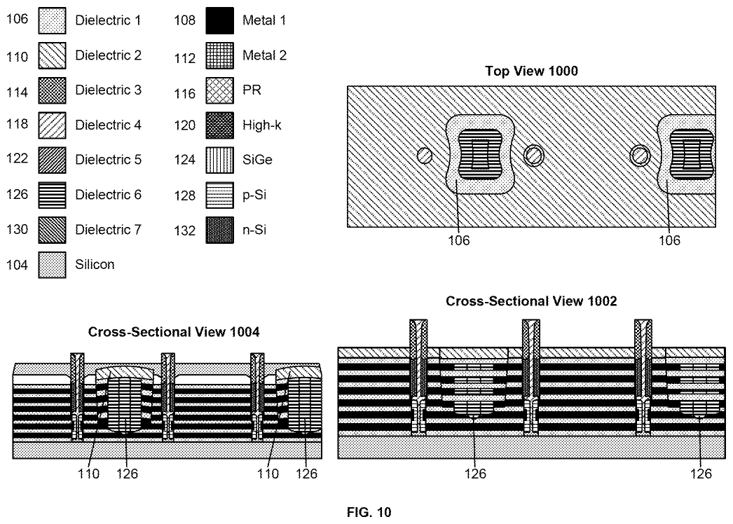

FIG. 10 illustrates a top view 1000 and cross-sectional views 1002 and 1004 of the next stage in the process flow. At this stage in the process flow, a selective deposition process (e.g., any suitable selective deposition technique, including ALD, CVD, PVD, etc.) is performed to form additional layers of the fifth dielectric material 126 on the new-exposed surfaces of the metal material 108 within the openings formed in the previous process step. As shown, this covers the newly-exposed surfaces of the layers of the metal material 108 in the openings with the fifth dielectric material 126. The fifth dielectric material 126 can protect the layers of the metal material 108 in subsequent etching steps (e.g., when forming the next steps in the staircase region). The selective deposition of the fifth dielectric material 126 on the first metal material 108 can be followed by a lateral and vertical (e.g., isotropic) etching of the second dielectric material 110, which can be similar to the process described in connection with FIG. 8. Then, another direction etching process of three layer-pairs of the first metal material 108 and the first dielectric material 106 can be performed, using techniques similar to those described in connection with FIG. 9. This exposes the next “step” in the staircase region, corresponding to the third layer (e.g., a source/drain contact) of the metal material 108.

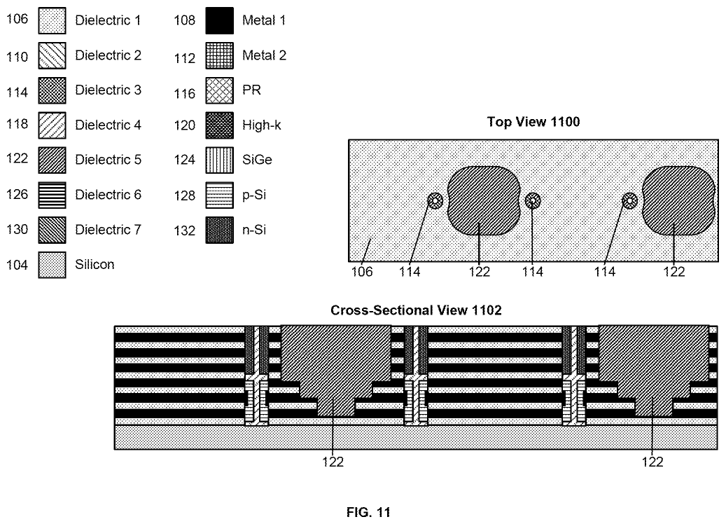

FIG. 11 illustrates a top view 1100 and a cross-sectional view 1102 of the next stage in the process flow. At this stage in the process flow, an isotropic etch of the fifth dielectric material 126 (and a thin layer of first dielectric material 106 and the first metal material 108) can be performed to clean up surfaces, and to remove the layer of the protective layers of the fifth dielectric material 126 formed on the metal material 108. The opening can then be filled with a sixth dielectric material 122 (shown in the legend as “Dielectric 5”). The sixth dielectric material 122 may be formed using any suitable material formation technique, including ALD, CVD, PVD, or PECVD, among others. Any remaining portions of the second dielectric material 110 can be removed using a suitable etching technique, and for any overburden can be removed by a CMP process.

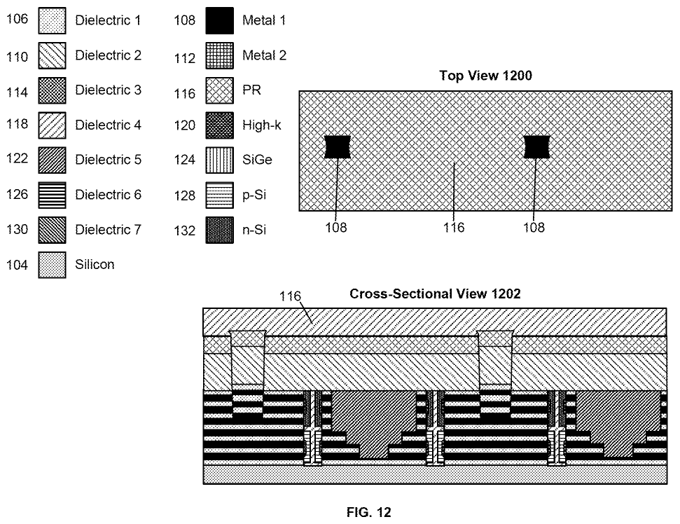

FIG. 12 illustrates a top view 1200 and a cross-sectional view 1202 of the next stage in the process flow. At this stage in the process flow, a layer of the second dielectric material 110 can be deposited on the top layer of the first dielectric material 106. The second dielectric material 110 can be formed using any suitable material deposition technique, and may be formed to a height that compensates for the subsequent etching steps used to form the second staircase region in the layer stack. After forming the layer of the second dielectric material 110, a mask material 116 can be patterned for use in forming the contacts for the upper transistor structure formed using the second semiconductive-behaving material 132. Openings can be formed in the mask material 116 using techniques similar to those described in connection with FIG. 6. The openings in the mask material 116 will be used to form the second staircase region for the contacts of the second transistor structure.

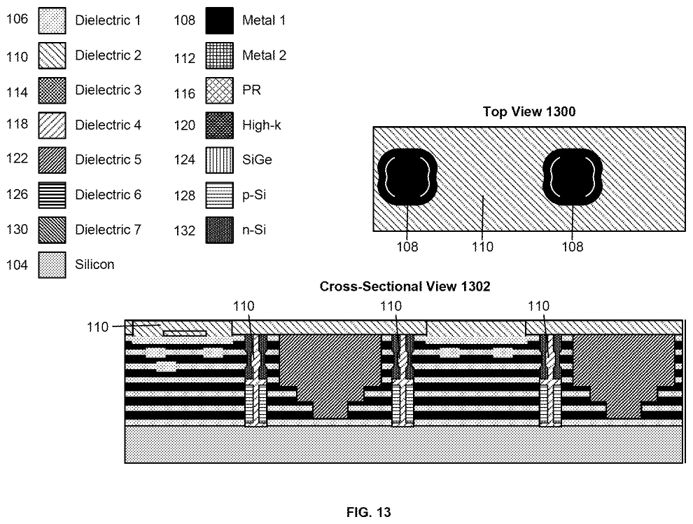

FIG. 13 illustrates a top view 1300 and a cross-sectional view 1302 of the next stage in the process flow. At this stage in the process flow, the mask material 116 can be removed using a suitable material removal technique. Then, a similar process as that described in connection with FIGS. 7-11 can be performed to form a second staircase region of metal layers within the layer stack for the upper transistor structure. As shown, the second staircase region is formed at a depth that corresponds to the top transistor structure. Any layers of the fifth dielectric material 126 can be removed using a suitable isotropic etching process.

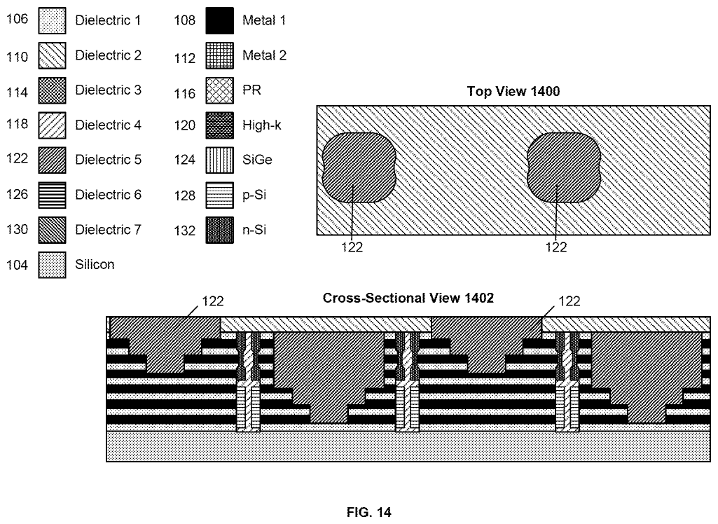

FIG. 14 illustrates a top view 1400 and a cross-sectional view 1402 of the next stage in the process flow. At this stage in the process flow, the openings that make up the second staircase region can be filled with the sixth dielectric material 122. To deposit the sixth dielectric material 122, techniques similar to those described in connection with FIG. 11 can be performed. However, in this stage in the process flow, the second dielectric material 110 is not removed from the top of the device. After forming the sixth dielectric material 122, any overburden can be removed using a CMP process.

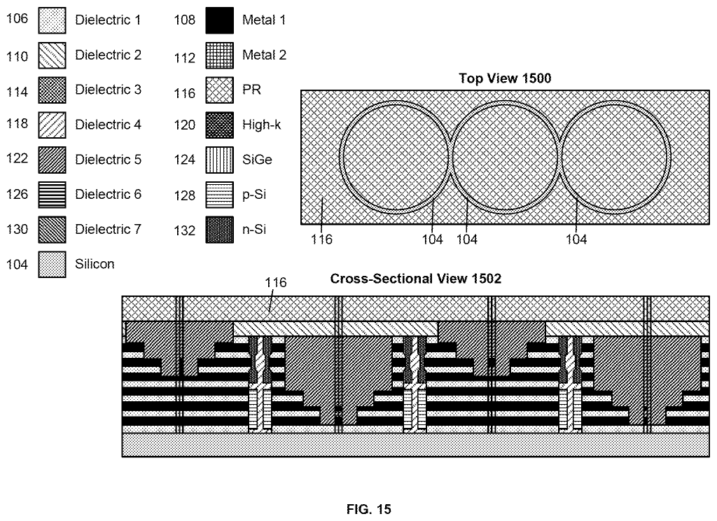

FIG. 15 illustrates a top view 1500 and a cross-sectional view 1502 of the next stage in the process flow. At this stage in the process flow, a layer of the mask material 116 is formed to define openings through a center portion of each staircase region. As shown, the mask material 116 can be patterned to define openings that are ring-shaped, or another shape that encircles or surrounds the vertical channel structures while passing through the staircase regions. The etching process used to form the openings can have an etch stop at the substrate layer 104, effectively isolating adjacent transistor structures from one another.

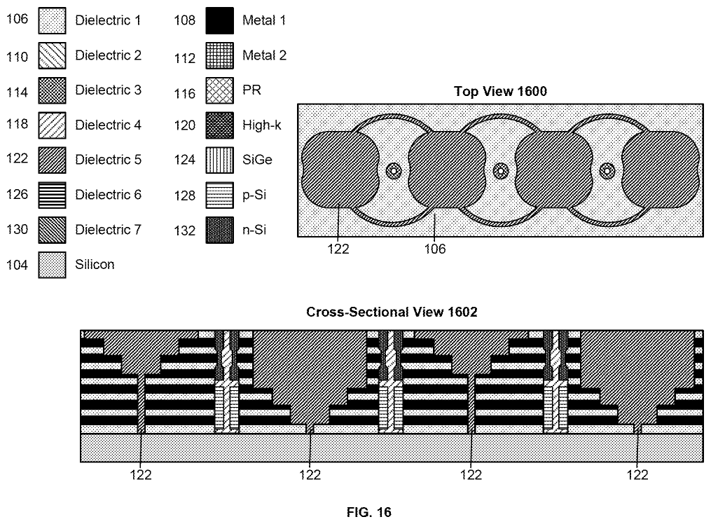

FIG. 16 illustrates a top view 1600 and a cross-sectional view 1602 of the next stage in the process flow. At this stage in the process flow, the mask material 116 can be removed using a suitable material removal technique, and the openings formed in the previous process step can be filled with the sixth dielectric material 122. Then, a CMP process may be performed to planarize the device. The CMP process may be performed to remove a predetermined amount of material from the device, such that an upper portion of the sixth dielectric material 122 and the second dielectric material 110 are removed from the device.

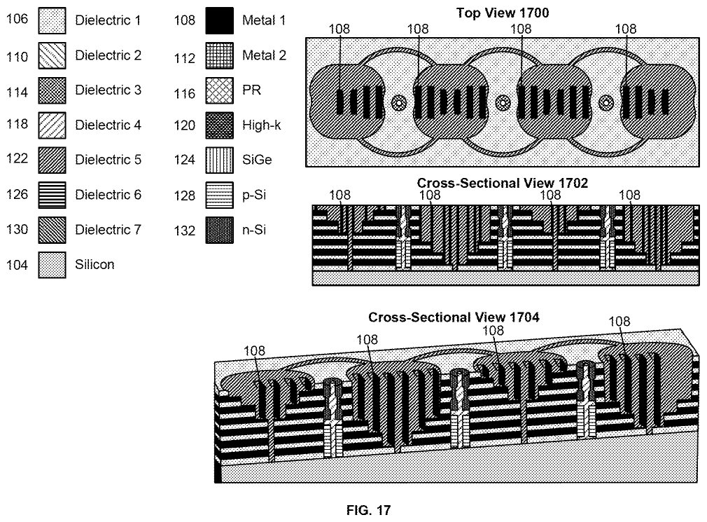

FIG. 17 illustrates a top view 1700 and cross-sectional views 1702 and 1704 of the next stage in the process flow. At this stage in the process flow, an etch mask (not pictured) can be formed to define contact openings through the sixth dielectric material 122 in each the stair case region. Each of the contact openings can be positioned over a respective step of the staircase region. An etching process can be performed in connection with the etch mask to remove the sixth dielectric material 122 and form the contact openings. Any suitable material etching process can be used, including but not limited to dry etching, wet etching, or plasma etching techniques, among others. The etch mask may be removed after the etching process is complete. The etching process may have an etch stop at the metal material 108. As shown, this creates openings that expose and extend upward from the metal material 108 at each step on each staircase region. The staircase regions and contact openings in the layer stack enables contacting each metal layer at a different spatial location from a top surface of the stack.

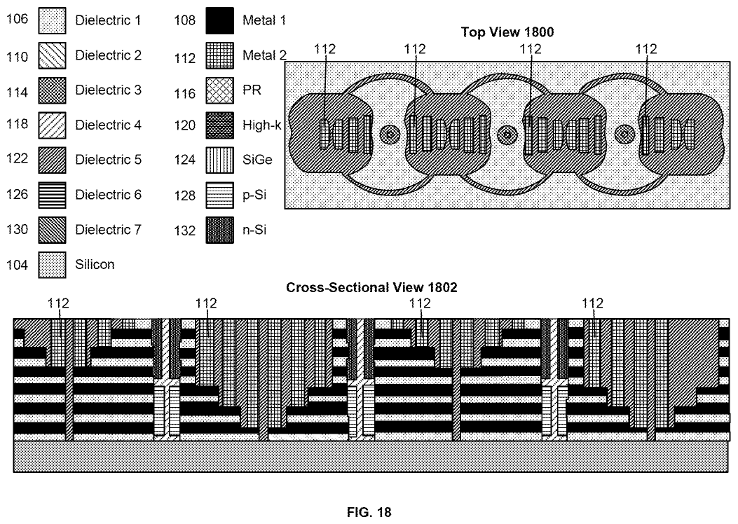

FIG. 18 illustrates a top view 1800 and a cross-sectional view 1802 of the next stage in the process flow. At this stage in the process flow, the contact openings formed in the previous process step can be filled with a second metal material 112 (shown in the legend as “Metal 2”). The second metal material 112 can be formed using any suitable material formation technique, including but not limited to ALD, CVD, PVD, or PECVD, among others. The second metal material 112 forms contacts for the source, drain, and gate layers for each transistor structure in the stack. After forming the second metal material 112, the device can be planarized using a CMP process.

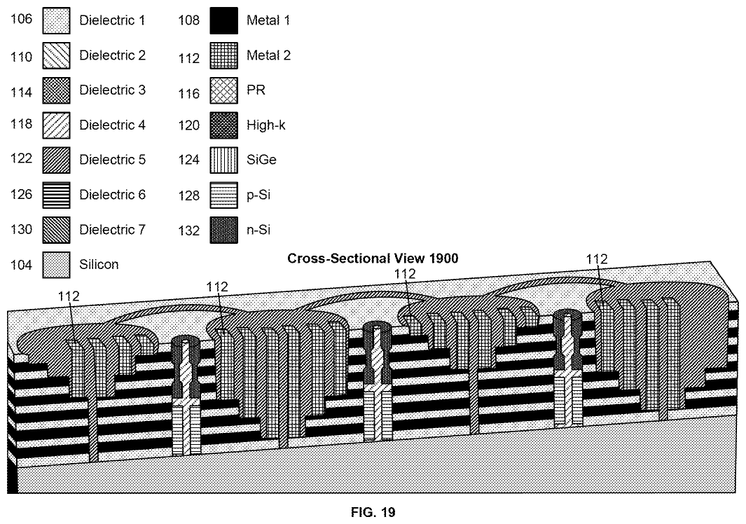

FIG. 19 illustrates a top view 1900 and a cross-sectional view 1902 of an example completed structure with top access contacts (formed from the second metal material 112) for the source layer, the drain layer, and the gate layer of 3D transistor structures. The transistor structures can include gate-all-around transistors, as described herein. The self-aligned dielectric hard mask etching of the openings described herein for different metal contacts are performed with few lithography steps.

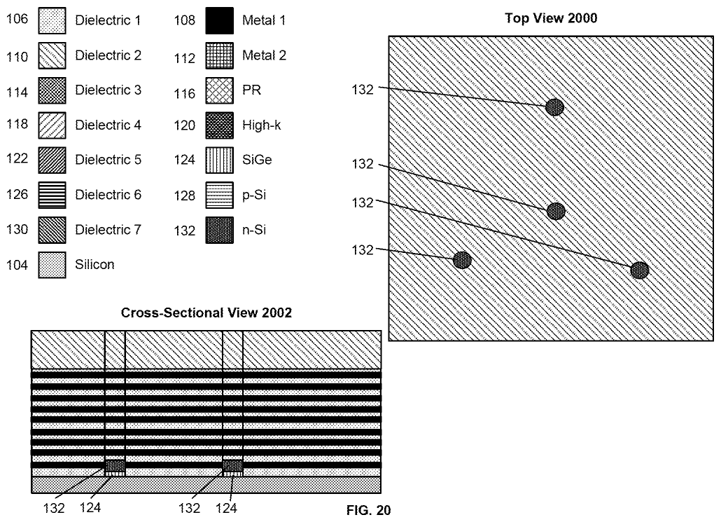

FIGS. 20-36 show various views of a second process flow to manufacture semiconductor devices with rotational symmetry. Each of FIGS. 20-36 generally refer to one or more process steps in a process flow, each of which are described in detail in connection with a respective Figure. For the purposes of simplicity and ease of visualization, some reference numbers may be omitted from some Figures. In FIGS. 20-36, an example process flow to manufacture an N-N-P device structure is described.

FIG. 20 illustrates a top view 2000 and a cross-sectional view 2002 of the first stage in the second process flow. At this stage in the process flow, a stack of layers can be formed using techniques similar to those described in connection with FIG. 1. As shown, the stack of layers can include nine layer-pairs of the first metal material 108 and the first dielectric material 106. After forming the layer stack, openings can be formed using techniques similar to those described in connection with FIG. 2. The openings may be formed in a predetermined pattern, shown in the top view 2000 as including three openings corresponding to points on a triangle with a single center opening. Then, a layer of the sacrificial material 124 and a layer of the second semiconductive-behaving material 132 (e.g., an n-type semiconductive material, such as n-doped Si, etc.) can be formed using techniques similar to those described in connection with FIG. 3.

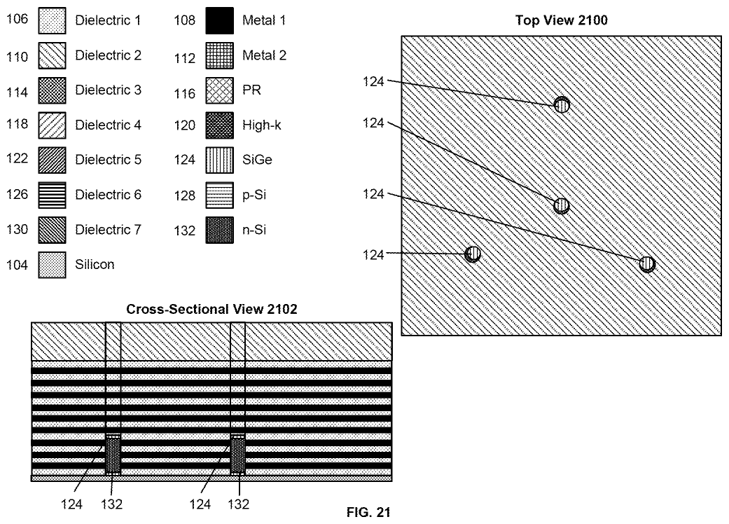

FIG. 21 illustrates a top view 2100 and a cross-sectional view 2102 of the next stage in the second process flow. At this stage in the process flow, a layer of the high-k dielectric material 120 can be formed as a gate dielectric, and the remaining second semiconductive-behaving material 132 can be formed to complete the bottom-most transistor structure, using techniques similar to those described in connection with FIGS. 3 and 4. A second layer of the sacrificial material 124 can then be formed on top of the second semiconductive-behaving material 132 using techniques similar to those described in connection with FIG. 4.

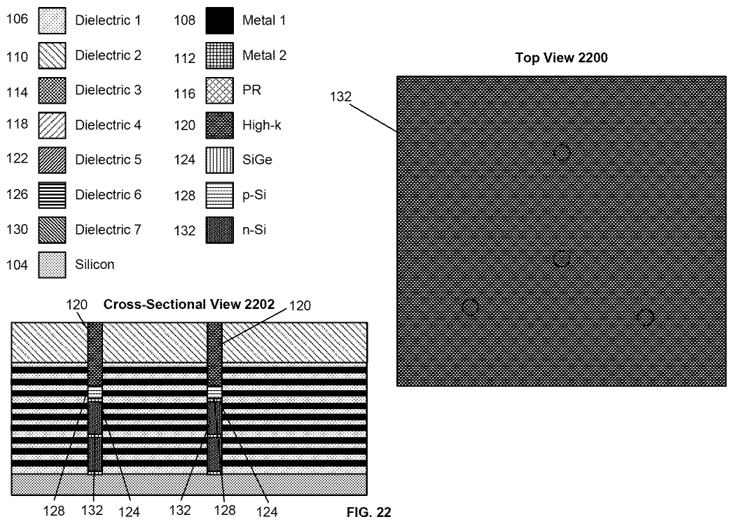

FIG. 22 illustrates a top view 2200 and a cross-sectional view 2202 of the next stage in the second process flow. At this stage in the process flow, the second transistor structure can be formed in the openings, using the second semiconductive-behaving material 132 as the channel structure material. The second transistor structure can be formed using techniques similar to those described in connection with FIGS. 4 and 21. This can include forming a second layer of the high-k dielectric material 120 to form the second gate dielectric for the second transistor structure. Then, a third layer of the sacrificial material 124 can be formed on the second layer of the second semiconductive-behaving material 132, using techniques similar to those described herein. A third transistor structure can then be formed using the semiconductive-behaving material 128, including a third layer of the high-k dielectric material 120 to form the third gate dielectric for the third transistor structure. The third layer of the high-k dielectric material 120 can be formed using techniques similar to those described in connection with FIGS. 3 and 4, by utilizing the third layer of the sacrificial material as a seed layer for the semi conductive-behaving material 128.

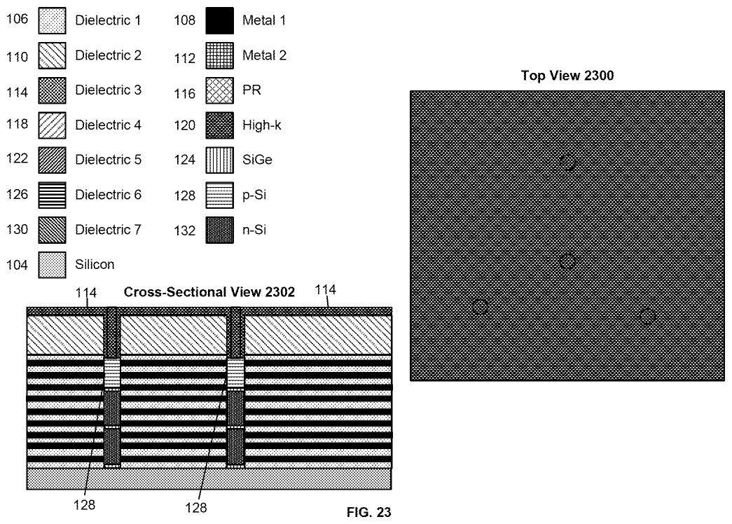

FIG. 23 illustrates a top view 2300 and a cross-sectional view 2302 of the next stage in the second process flow. At this stage in the process flow, the third transistor structure can be completed using techniques similar to those described in connection with FIG. 4, and a layer of the third dielectric material 114 can be deposited using techniques similar to those described in connection with FIG. 5. As shown, the layer of the third dielectric material 114 can be formed at a predetermined thickness such that it does not entirely fill the openings at the top of the device. This forms a self-aligning opening that can be used to form a core through the device using techniques similar to those described herein.

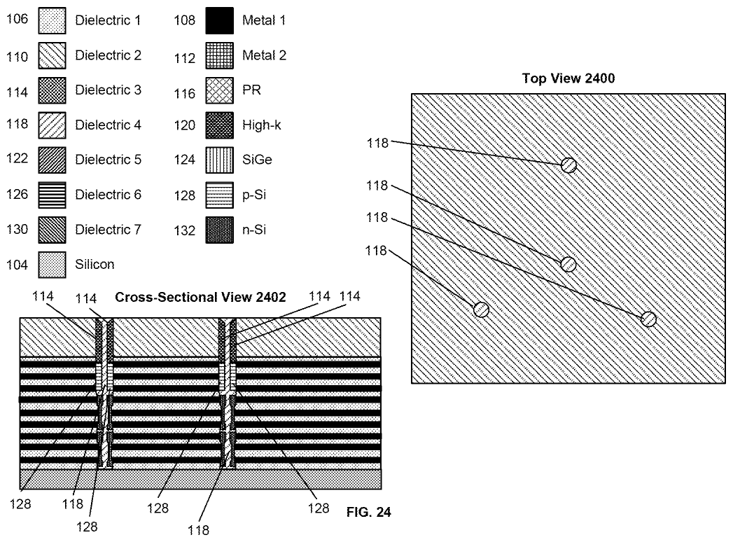

FIG. 24 illustrates a top view 2400 and a cross-sectional view 2402 of the next stage in the second process flow. At this stage in the process flow, core openings can be formed through the transistor structures formed in prior process steps. The core openings can be formed using the techniques described in connection with FIG. 5. The layers of the sacrificial material 124 can be removed, and the core openings and the openings left by removing the sacrificial material 124 can be filled with the fourth dielectric material 118, as described in further detail in connection with FIG. 5. The core opening can extend to the substrate 104.

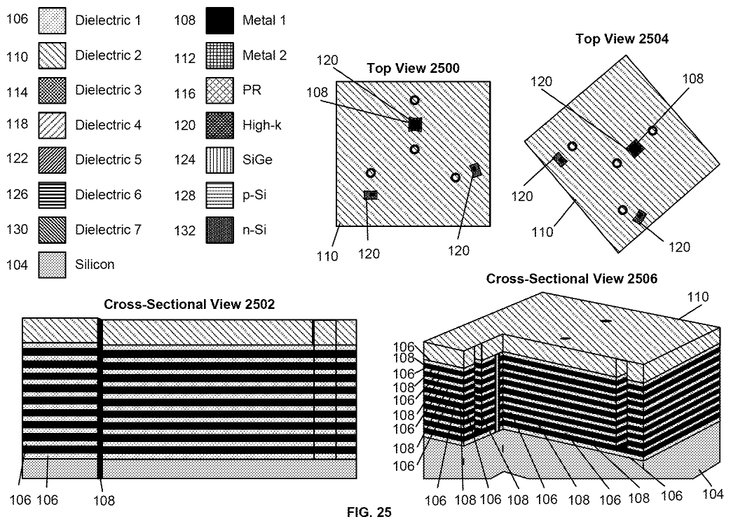

FIG. 25 illustrates top views 2500 and 2504 and cross-sectional views 2502 and 2506 of the next stage in the second process flow. At this stage in the process flow, masking and directional etching are performed to begin the process of forming staircase regions for each of the transistor structures. The openings can be formed by performing etching techniques similar to those described in connection with FIG. 6.

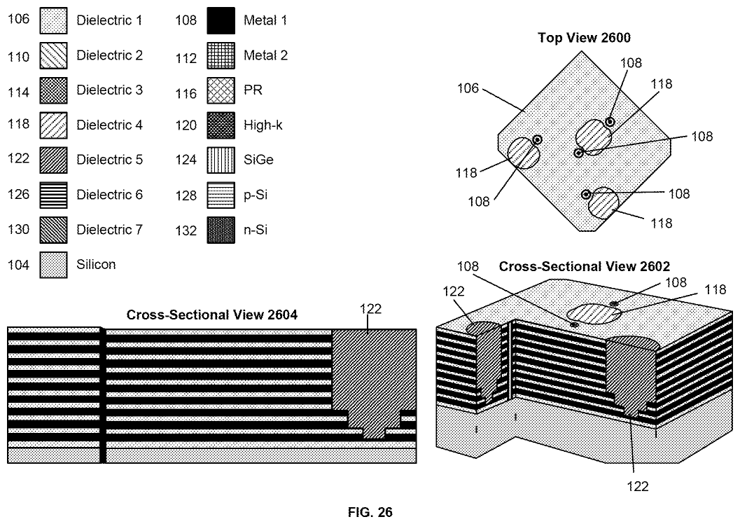

FIG. 26 illustrates a top view 2600 and cross-sectional views 2602, 2604 of the next stage in the second process flow. At this stage in the process flow, corresponding staircase regions can be formed for the bottom-most transistor structures in the layer stack. The staircase regions can be formed and filled with the sixth dielectric material 122 using the techniques described in connection with FIGS. 7-11. As shown, in some implementations, a staircase structure may correspond to two or more transistor structures (e.g., formed between the transistor structures, as shown in the top view 2600.

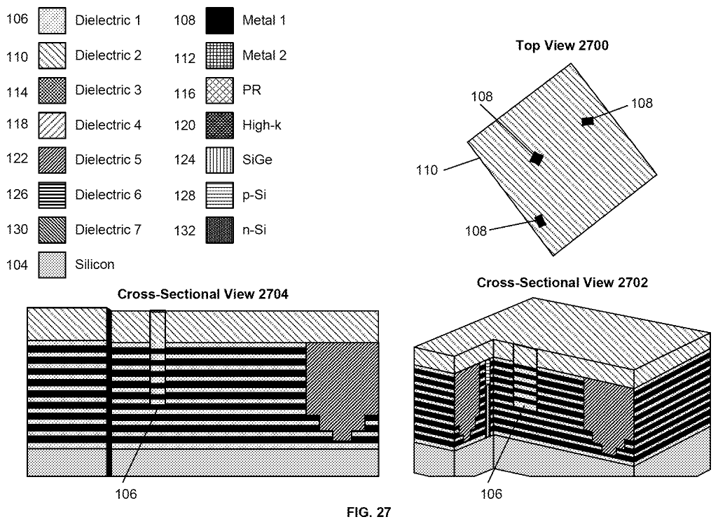

FIG. 27 illustrates a top view 2700 and cross-sectional views 2702, 2704 of the next stage in the second process flow. At this stage in the process flow, masking and directional etching are performed to begin the process of forming second staircase regions for each of the transistor structures. The second staircase regions can be formed for the middle transistor structures in the layer stack. The openings can be formed by performing etching techniques similar to those described in connection with FIG. 12.

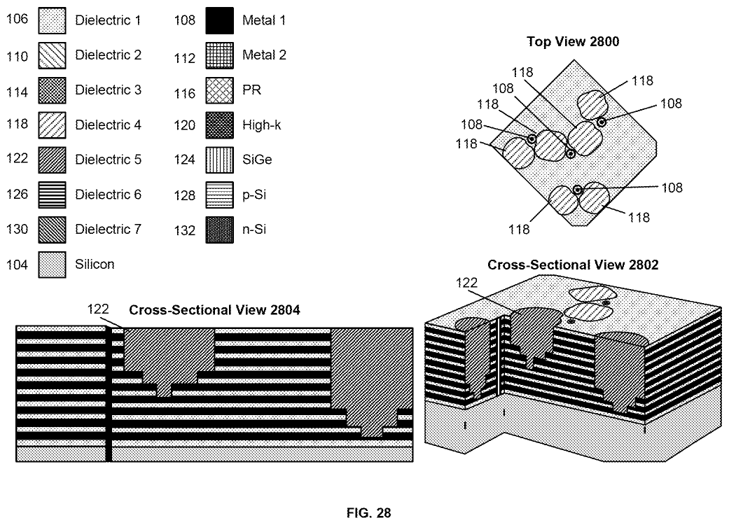

FIG. 28 illustrates a top view 2800 and cross-sectional views 2802, 2804 of the next stage in the second process flow. At this stage in the process flow, corresponding staircase regions can be formed for the middle transistor structures in the layer stack. The staircase regions can be formed and filled with the sixth dielectric material 122 using the techniques described in connection with FIGS. 12-14. As shown, in some implementations, a staircase structure may correspond to two or more transistor structures (e.g., formed between the transistor structures, as shown in the top view 2800.

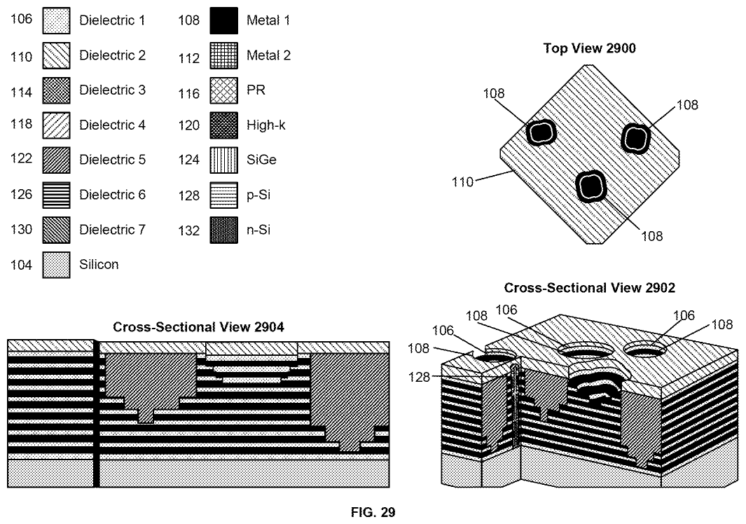

FIG. 29 illustrates a top view 2900 and cross-sectional views 2902, 2904 of the next stage in the second process flow. At this stage in the process flow, corresponding staircase regions can be formed for the top-most transistor structures in the layer stack. The staircase regions can be formed and filled with the sixth dielectric material 122 using the techniques described in connection with FIGS. 12-14.

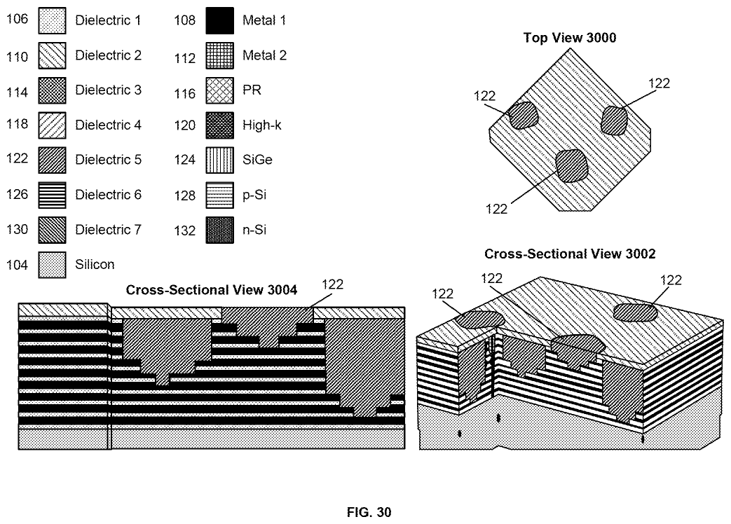

FIG. 30 illustrates a top view 3000 and cross-sectional views 3002, 3004 of the next stage in the second process flow. At this stage in the process flow, the staircase regions formed for the top-most transistor structures can be filled with the sixth dielectric material 122 using the techniques described in connection with FIG. 14. A CMP process may then be performed to planarize the device.

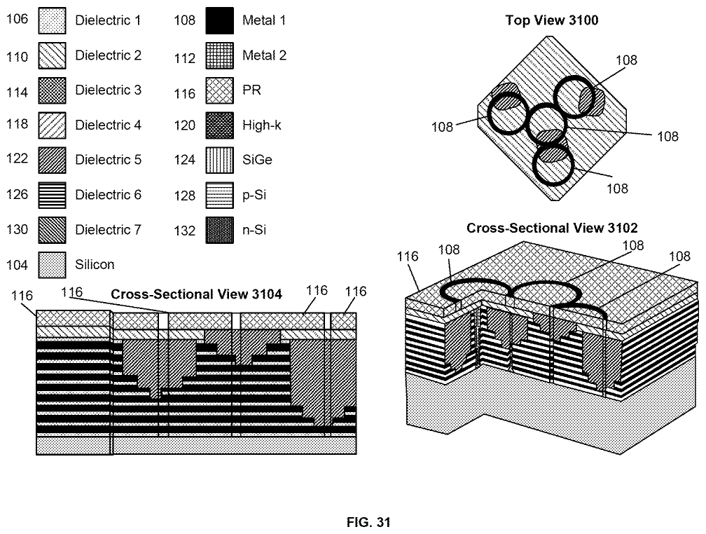

FIG. 31 illustrates a top view 3100 and cross-sectional views 3102, 3104 of the next stage in the second process flow. At this stage in the process flow, a mask material 115 can be patterned to define openings using the techniques described in connection with FIG. 15. The openings can be defined as ring-shaped, or another shape that encircles or surrounds the transistor structures while passing through the staircase regions. As shown, each of the ring shapes contact one another, and may be defined to intersect with a center of each of the staircase regions. The etching process used to form the openings can have an etch stop at the substrate layer 104, effectively isolating adjacent transistor structures from one another.

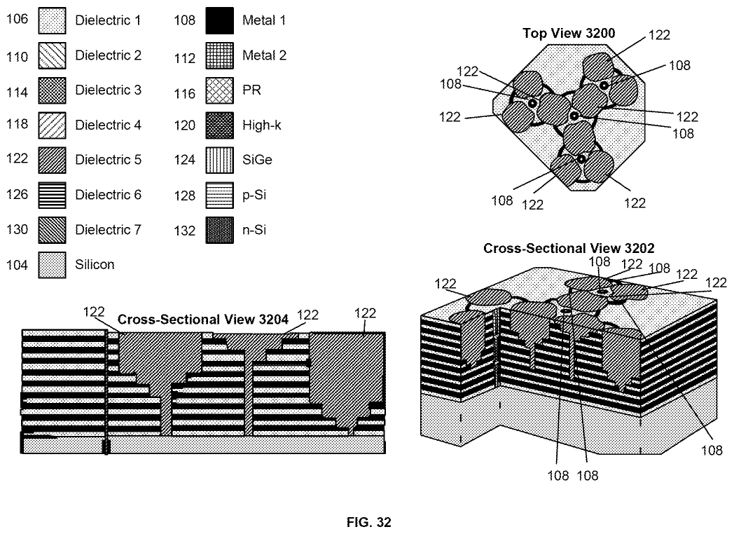

FIG. 32 illustrates a top view 3200 and cross-sectional views 3202, 3204 of the next stage in the second process flow. At this stage in the process flow, the mask material 116 can be removed using a suitable material removal technique, and the openings formed in the previous process step can be filled with the sixth dielectric material 122. Then, a CMP process may be performed to planarize the device. The CMP process may be performed to remove a predetermined amount of material from the device, such that an upper portion of the sixth dielectric material 122 and the second dielectric material 110 are removed from the device.

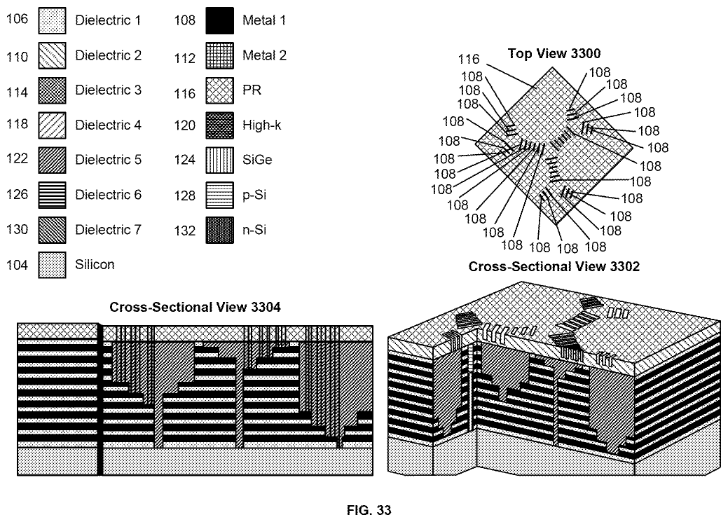

FIG. 33 illustrates a top view 3300 and cross-sectional views 3302, 3304 of the next stage in the second process flow. At this stage in the process flow, a mask material 116 is patterned to define openings for contacts to respective metal layers in the layer stack on the staircase regions. To do so, techniques similar to those described in connection with FIG. 17 can be performed.

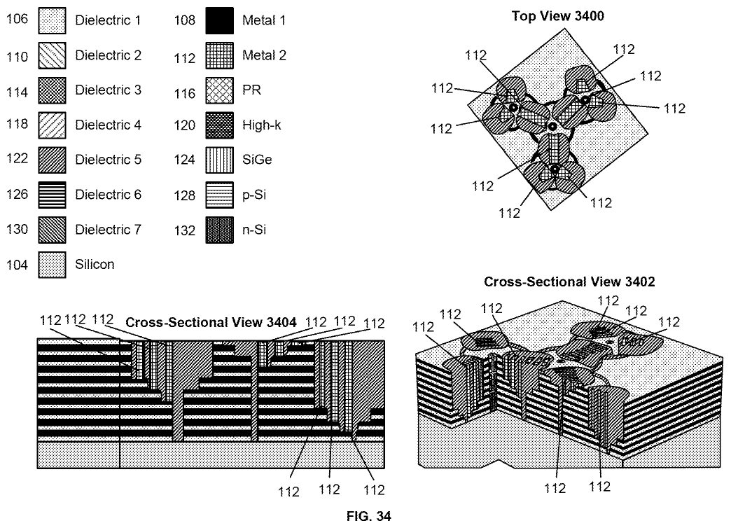

FIG. 34 illustrates a top view 3400 and cross-sectional views 3402, 3404 of the next stage in the second process flow. At this stage in the process flow, the openings formed in the previous process stage can be filled with the second metal material 112. To do so, the techniques described in connection with FIG. 18 can be performed.

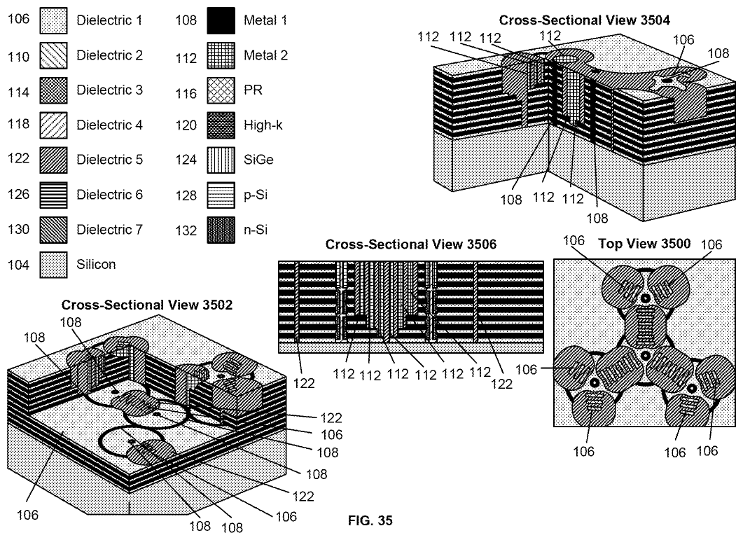

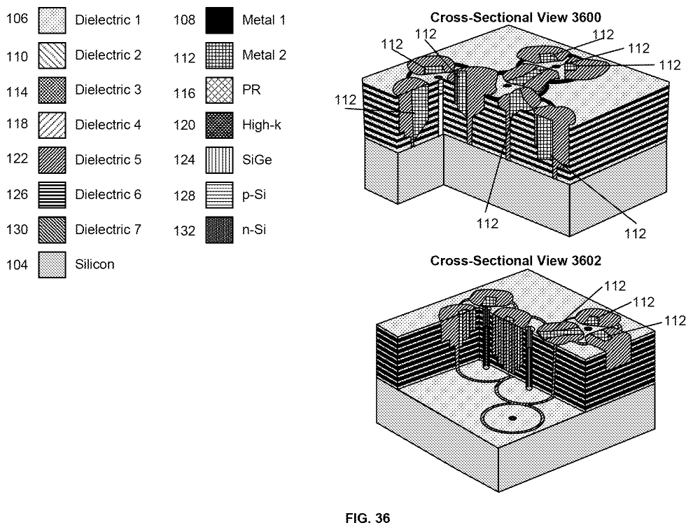

FIG. 35 illustrates a top view 3500 and cross-sectional views 3502, 3504, and 3506 an example completed structure with top access contacts (formed from the second metal material 112) for the source layer, the drain layer, and the gate layer of each 3D transistor structure in the layer stack. As shown, contacts are formed in corresponding staircase regions for each of the bottom, middle, and top transistor structures. FIG. 36 illustrates cross-sectional views 3600 and 3602 of the example completed structure shown in FIG. 35.

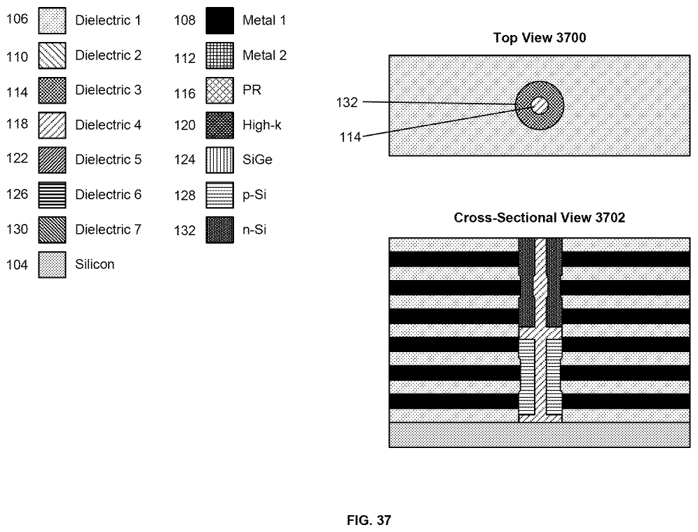

FIGS. 37-49 show various views of a third process flow to manufacture semiconductor devices. Each of the FIGS. 37-49 generally refer to one or more process steps in a process flow, each of which are described in detail in connection with a respective Figure. For the purposes of simplicity and ease of visualization, some reference numbers may be omitted from some Figures. In FIGS. 37-49, an example process flow including an alternative embodiment for metal routing. This includes forming staircase regions as linear or rectangular regions extending at given radial directions from a center of the vertical channel structure as seen from a top view. This embodiment provides a self-aligned contained cap layer etching technique. Each contact opening for a given vertical channel structure extends at a radial direction from a center of the vertical channel structure stack. The number of regions extending from each transistor structure is based on number of transistors in the vertical stack. Formation of each staircase region is similar to staircase formation as described above.

FIG. 37 illustrates a top view 3700 and a cross-sectional view 3702 of the first stage in the third process flow. At this stage in the process flow, a stack of layers can be formed using techniques similar to those described in connection with FIG. 1. As shown, the stack of layers can include six layer-pairs of the first metal material 108 and the first dielectric material 108. After forming the layer stack, openings can be formed using techniques similar to those described in connection with FIG. 2. The openings may be formed in a predetermined pattern, shown in the top view 3600 as including three openings corresponding to points on a triangle with a single center opening. Then, transistor structures can be formed in the openings using techniques similar to those described in connection with FIGS. 3-5. The device can be planarized to remove the top layer of the third dielectric material 114, the top portion of the fourth dielectric material 118, and the top layer of the second dielectric material 110 can be removed such that the second semiconductive-behaving material 132 is exposed at the top of the device.

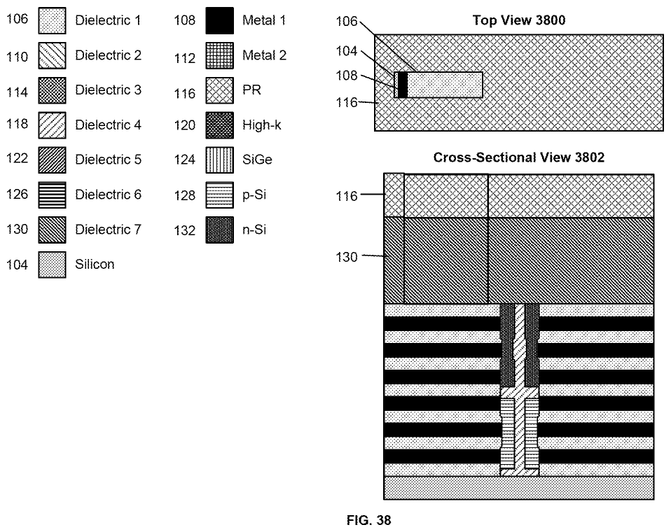

FIG. 38 illustrates a top view 3800 and a cross-sectional view 3802 of the next stage in the third process flow. At this stage in the process flow, a layer of a seventh dielectric material 130 can be formed on top of the device using a suitable material deposition technique, such as ALD, CVD, PVD, or PECVD, among others. Then, a layer of the mask material 116 can be patterned on top of the seventh dielectric material 130. The mask material 116 can be patterned to define a contact opening that extends at a radial direction from a center of the transistor structures, as shown. The mask material 116 may be formed using the techniques described herein. The seventh dielectric material 130 can then be directionally etched with an etch stop at the top of the first dielectric material 106, as shown. Any suitable etching technique may be used to etch the seventh dielectric material 130.

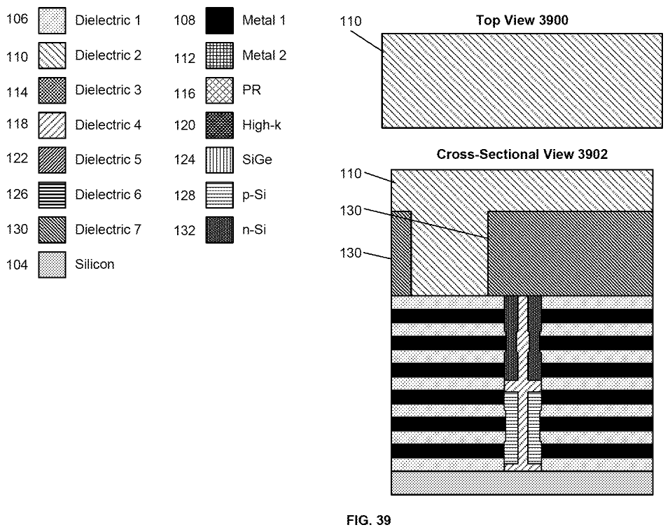

FIG. 39 illustrates a top view 3900 and a cross-sectional view 3902 of the next stage in the third process flow. At this stage in the process flow, the mask material 116 can be removed using a suitable material removal technique. Then, the second dielectric material 110 can be deposited to fill the opening formed in the previous process step. The second dielectric material 110 can be deposited to form a uniform layer on top of the device, as shown in the cross-sectional view 3902. A CMP process may then be performed to planarize the device. The layer of the second dielectric material 110 can act as a buffer for subsequent etching processes.

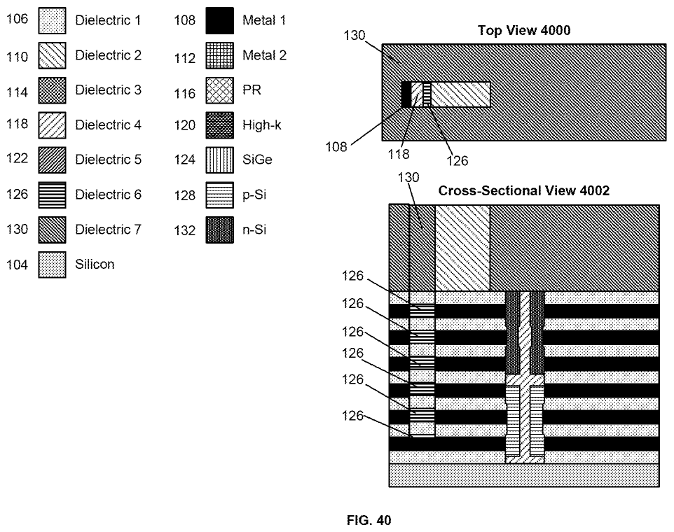

FIG. 40 illustrates a top view 4000 and a cross-sectional view 4002 of the next stage in the third process flow. At this stage in the process flow, the second dielectric material 110, the first dielectric material 106, and the first metal material 108 can be directionally etched, with an etch stop process on the bottom layer of the metal material 108. This etching process can be similar to the process described in connection with FIG. 6. As shown, the etching process can be through a portion of the second dielectric material 110 at the top of the device. Other portions of the second dielectric material 110 can remain for subsequent etching steps to define other steps in the staircase structure. After the etching process, the fifth dielectric material 126 can be selectively deposited on the metal material 108 using techniques described in connection with FIG. 7.

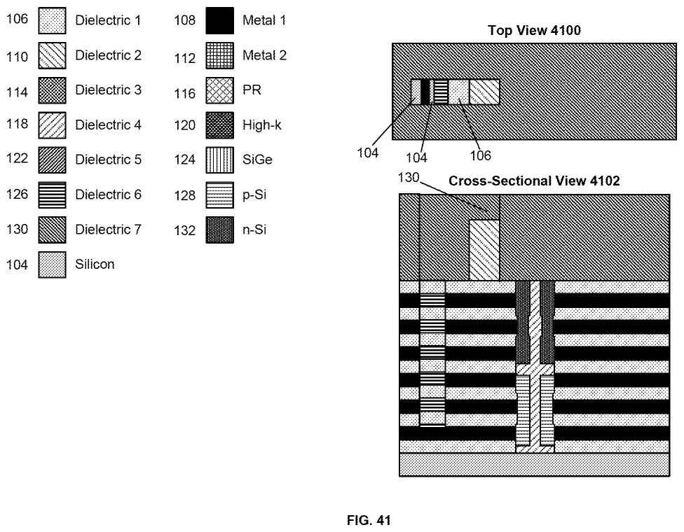

FIG. 41 illustrates a top view 4100 and a cross-sectional view 4102 of the next stage in the third process flow. At this stage in the process flow, an isotropic etch of the second dielectric material 116 can be performed. The isotropic etching process can be any suitable type of etching process, including but not limited to dry etching, wet etching, or plasma etching techniques, among others. The isotropic etch of the second dielectric material 110 can be performed to create a self-aligned opening for the contacts. As shown, this exposes a portion of the first dielectric material 106 in the opening formed in the seventh dielectric material 130.

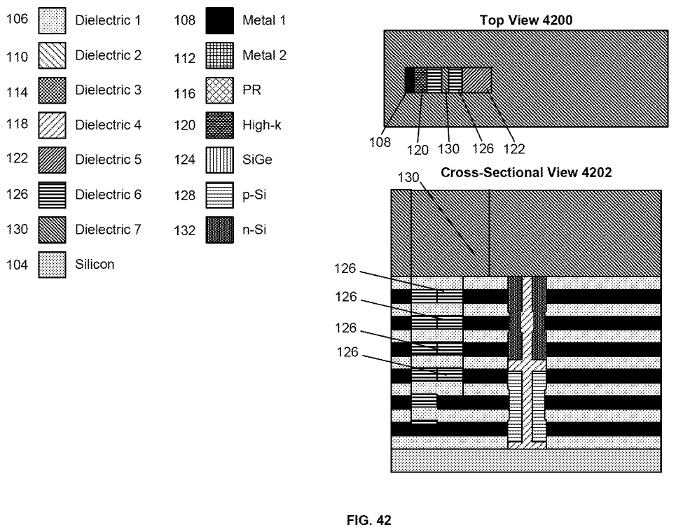

FIG. 42 illustrates a top view 4200 and a cross-sectional view 4202 of the next stage in the third process flow. At this stage in the process flow, steps similar to those described in connection with FIG. 40 can be performed to define a second step, adjacent to the first step. In this case, the step has an etch stop at the second layer (from the substrate 104) of the metal material 108, exposing the second layer of the metal material 108 in the newly-formed opening. As described in connection with FIG. 40, the fifth dielectric material 126 can be selectively formed on the now-exposed metal material 108 to protect the metal material from subsequent etching steps.

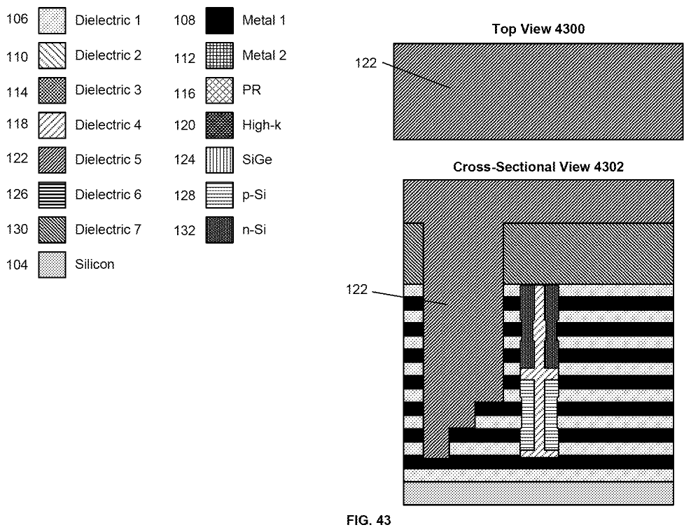

FIG. 43 illustrates a top view 4300 and a cross-sectional view 4302 of the next stage in the third process flow. At this stage in the process flow, steps similar to those described in connection with FIGS. 40-42 can be performed to form a third step, which exposes the third layer (from the substrate) of the metal material 108 a newly formed opening. Then, the layers of the fifth dielectric material 126 can be removed using techniques similar to those described in connection with FIG. 11. Then, the openings can be deposit filled with the sixth dielectric material 122, using techniques similar to those described in connection with FIG. 11. As shown, a uniform layer of the sixth dielectric material 122 can be formed on the seventh dielectric material 130.

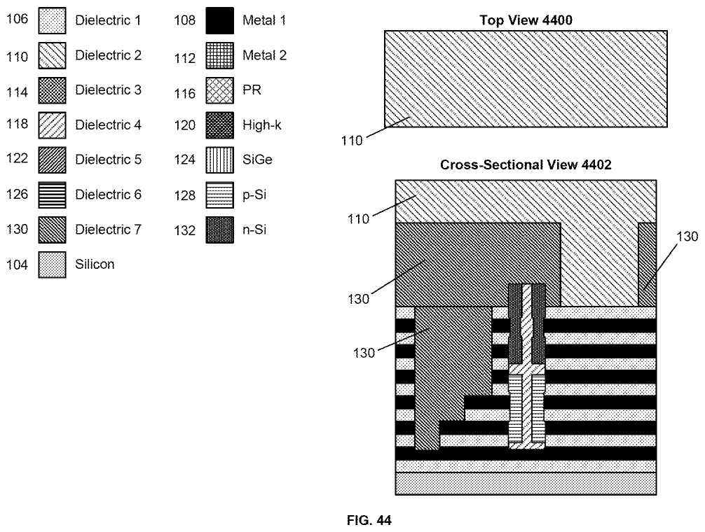

FIG. 44 illustrates a top view 4400 and a cross-sectional view 4402 of the next stage in the third process flow. At this stage in the process flow, the layers of the sixth dielectric material and the seventh dielectric material 130 can be removed, and a CMP process can be performed to planarize the device. Then, another layer of the seventh dielectric material 130 can be formed, an additional contact opening can be formed, and a layer of the second dielectric material 110 can be deposited, using the techniques described in connection with FIGS. 38 and 39.

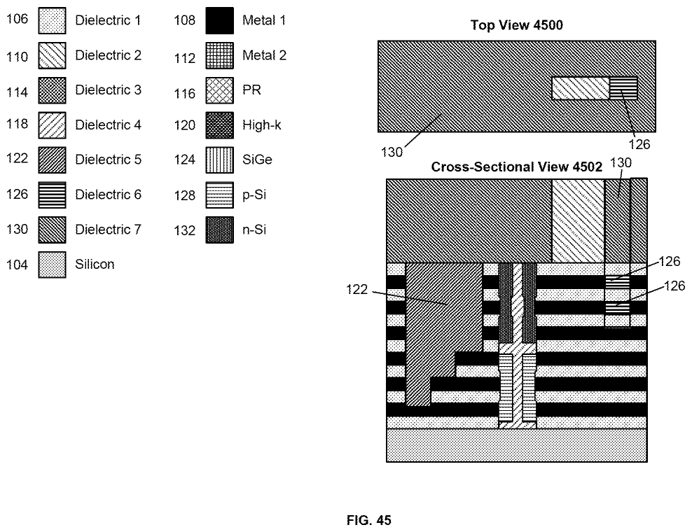

FIG. 45 illustrates a top view 4500 and a cross-sectional view 4502 of the next stage in the third process flow. At this stage in the process flow, the second dielectric material 110, the first dielectric material 106, and the first metal material 108 can be directionally etched, with an etch stop process on the bottom-most layer of the metal material 108 of the second transistor structure. To do so, techniques similar to those described in connection with FIG. 40 can be performed.

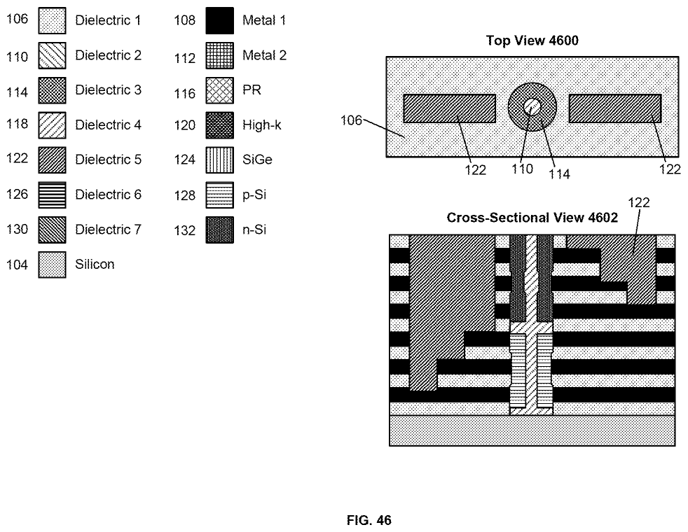

FIG. 46 illustrates a top view 4600 and a cross-sectional view 4602 of the next stage in the third process flow. At this stage in the process flow, a corresponding staircase region can be formed for the top-most transistor structure using techniques similar to those described in connection with FIGS. 41-43. Then, the top layers of the seventh dielectric material 130 and any additional sixth dielectric material 122 can be removed, and the device can be planarized using a CMP process.

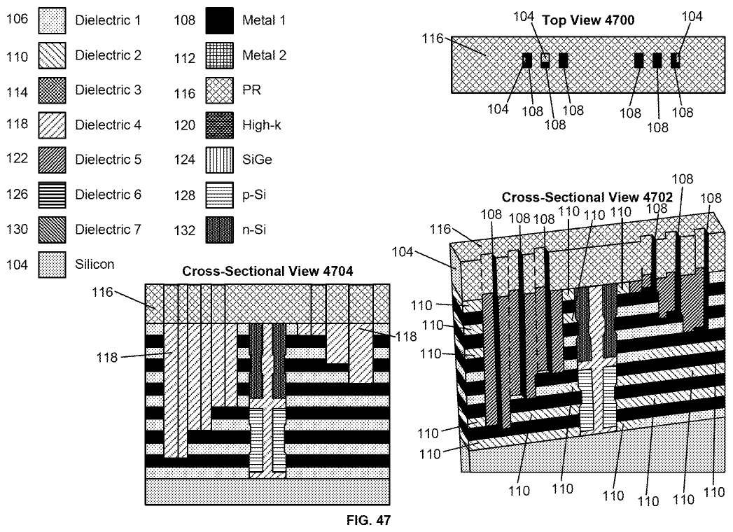

FIG. 47 illustrates a top view 4700 and cross-sectional views 4702 and 4704 of the next stage in the third process flow. At this stage in the process flow, contact openings can be formed in the sixth dielectric material 122 using techniques similar to those described in connection with FIG. 17. As shown, and as described herein, the contact holes can be etched using an etching mask (not pictured), which can define the positions of the contact holes. The etching process can have an etch stop at the metal material 108, such that a respective metal layer is exposed in each of the contact openings. Each of the contact openings can be positioned over a respective step in the staircase regions formed in previous process steps.

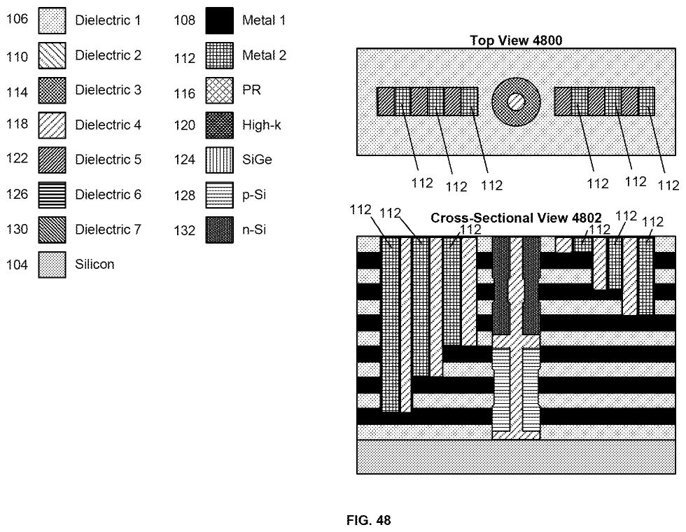

FIG. 48 illustrates a top view 4800 and a cross-sectional view 4802 of the next stage in the third process flow. At this stage in the process flow, the contact holes formed in the previous process step can be deposit-filled with the second metal material 112. To do so, techniques similar to those described in connection with FIG. 18 can be performed. After forming the second metal material 112, a CMP process may be performed to planarize the device.

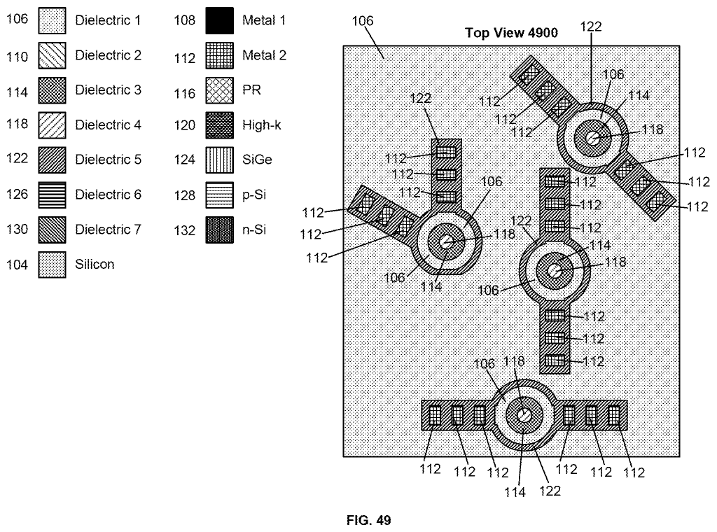

FIG. 49 illustrates a top view 4900 an example completed structure with top access contacts (formed from the second metal material 112) for the source layer, the drain layer, and the gate layer of the 3D transistor structures formed in the previous process step. The transistor structures can include gate-all-around transistors, as described herein. As shown, the staircase regions can extend at any radial direction from the vertical transistor stack providing design flexibility and high density routing to chip designers. Additionally, circular ring openings can be formed to isolate each transistor, which can be deposit-filled with the sixth dielectric material 122. To form the circular openings, the techniques described in connection with FIG. 15-16 or 31-32 can be performed.

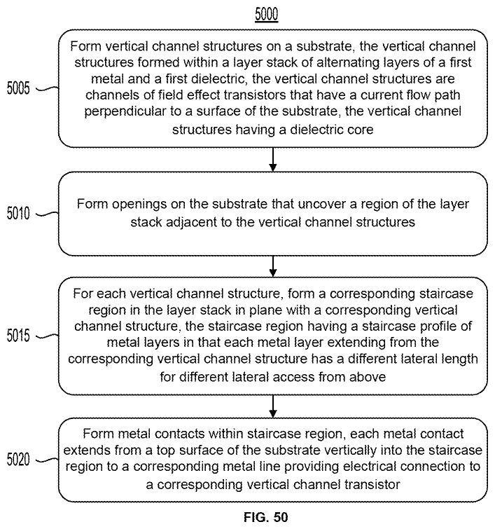

FIG. 50 illustrates a flow diagram of a method 5000 for microfabrication using the process flows described in connection with FIGS. 1-49, according to an embodiment. The method 5000 may include steps 5005-5020. However, other embodiments may include additional or alternative steps, or may omit one or more steps altogether.

Referring to step 5005, the method 5000 includes forming vertical channel structures (e.g., the semiconductive-behaving material 128 or the second semiconductive-behaving material 132) on a substrate (e.g., the substrate 104). The vertical channel structures can be formed within a layer stack of alternating layers of a first metal (e.g., the metal material 108) and a first dielectric (e.g., the dielectric material 106). The vertical channel structures are channels of field effect transistors that have a current flow path perpendicular to a surface of the substrate. The vertical channel structures having a dielectric core. In some implementations, the forming the vertical channel structures may include forming a second field effect transistor on top of a first field effect transistor. To form the transistor structures, the techniques described in connection with FIG. 1-5, 20-24, or 37 can be performed. In some implementations, any number of transistor structures can be formed in the stack. The field effect transistors may be an n-type transistor structure or a p-type transistor structure. High-k dielectric materials (e.g., the high-k dielectric material 120) can be formed in contact with the vertical channel structures and a gate metal layer (e.g., a layer of the metal material 108).

Referring to step 5010, the method 5000 includes forming openings on the substrate that uncover a region of the layer stack adjacent to the vertical channel structures. To form the openings, the process steps described in connection with FIGS. 6, 12, 25, 27, and 29 can be performed. The openings can expose one or more portions of the metal layers in the stack.

Referring to step 5015, the method 5000 includes, for each vertical channel structure, forming a corresponding staircase region in the layer stack in plane with a corresponding vertical channel structure. The staircase region having a staircase profile of metal layers in that each metal layer extending from the corresponding vertical channel structure has a different lateral length for different lateral access from above. To form the staircase structures, the process steps described in connection with FIGS. 6-11, 12-14, 25-26, 27-28, and 29-30 can be performed.

Referring to step 5020, the method 5000 includes forming metal contacts (e.g., the second metal material 112) within staircase region. Each metal contact extends from a top surface of the substrate vertically into the staircase region to a corresponding metal line providing electrical connection to a corresponding vertical channel transistor coupled to the plurality of metal layers exposed in the staircase region. In some implementations, the metal contacts are formed to be electrically isolated from each other by a dielectric material (e.g., the sixth dielectric material 122). Metal contacts can be formed for each staircase region formed in step 5015. To form the metal contacts, the process steps described in connection with FIG. 17-18 or 33-34 can be performed.

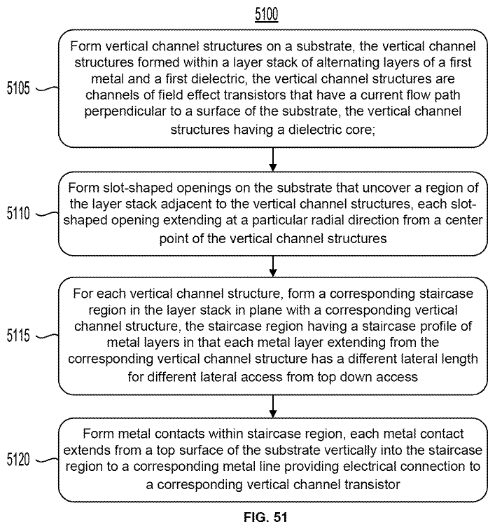

FIG. 51 illustrates a flow diagram of a method 5100 for microfabrication using the process flows described in connection with FIGS. 1-49, according to an embodiment. The method 5100 may include steps 5105-5120. However, other embodiments may include additional or alternative steps, or may omit one or more steps altogether.

Referring to step 5105, the method 5100 includes forming vertical channel structures (e.g., the semiconductive-behaving material 128 or the second semiconductive-behaving material 132) on a substrate (e.g., the substrate 104). The vertical channel structures can be formed within a layer stack of alternating layers of a first metal (e.g., the metal material 108) and a first dielectric (e.g., the dielectric material 106). In some implementations, the forming the vertical channel structures may include forming a second field effect transistor on top of a first field effect transistor. To form the transistor structures, the techniques described in connection with FIG. 1-5, 20-24, or 37 can be performed. In some implementations, any number of transistor structures can be formed in the stack. The field effect transistors may be an n-type transistor structure or a p-type transistor structure. High-k dielectric materials (e.g., the high-k dielectric material 120) can be formed in contact with the vertical channel structures and a gate metal layer (e.g., a layer of the metal material 108).

Referring to step 5110, the method 5100 includes forming slot-shaped openings on the substrate that uncover a region of the layer stack adjacent to the vertical channel structures. Each slot-shaped opening extending at a particular radial direction from a center point of the vertical channel structures. To form the slot-shaped openings, the process steps described in connection with FIGS. 38-40 can be performed. The slot-shaped openings can expose one or more portions of the metal layers in the stack.

Referring to step 5115, the method 5100 includes, for each vertical channel structure, forming a corresponding staircase region in the layer stack in plane with a corresponding vertical channel structure. The staircase region having a staircase profile of metal layers in that each metal layer extending from the corresponding vertical channel structure has a different lateral length for different lateral access from above. To form the staircase structures, the techniques described in connection with FIG. 38-43 or 44-46 can be performed. In some implementations, an opening in the stack can be formed that isolates the transistor structure from a second transistor structure in the stack.

Referring to step 5120, the method 5100 includes forming metal contacts (e.g., the second metal material 112) within staircase region. Each metal contact extends from a top surface of the substrate vertically into the staircase region to a corresponding metal line providing electrical connection to a corresponding vertical channel transistor coupled to the plurality of metal layers exposed in the staircase region. In some implementations, the metal contacts are formed to be electrically isolated from each other by a dielectric material (e.g., the sixth dielectric material 122). Metal contacts can be formed for each staircase region formed in step 5115. To form the metal contacts, the process steps described in connection with FIGS. 47-48 can be performed.

In some implementations, the staircase region can be formed by forming a slot-shaped opening that exposes at least one metal layer of the plurality of metal layers. The slot-shaped opening can extend at a particular radial direction from a center point of the transistor structure. The opening can be a circular ring opening that surrounds the transistor structure. To form the opening, the techniques described in connection with FIG. 15-16, 31-32, or 49 can be performed.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for microfabrication, the method comprising:
forming vertical channel structures on a substrate, the vertical channel structures formed within a layer stack of alternating layers of a first metal and a first dielectric, the vertical channel structures having a current flow path perpendicular to a surface of the substrate, the vertical channel structures having a dielectric core;
forming openings on the substrate that uncover a region of the layer stack adjacent to the vertical channel structures;
for each vertical channel structure, forming a corresponding staircase region in the layer stack in plane with a corresponding vertical channel structure, the staircase region having a staircase profile of metal layers in that each metal layer extending from the corresponding vertical channel structure has a different lateral length for different lateral access from above; and
forming metal contacts within the staircase region, each metal contact extending from a top surface of the substrate vertically into the staircase region to a corresponding metal line providing electrical connection to a corresponding vertical channel structure.

2. The method of claim 1, wherein a given staircase region is positioned between two vertical channel structures, further comprising isolating the layers of metal lines between the two vertical channel structures within the given staircase region.

3. The method of claim 2, wherein isolating the layers of metal lines between the two vertical channel structures includes etching a ring structure around each vertical channel structure.

4. The method of claim 1, further comprising forming a second dielectric in the staircase region formed for each vertical channel structure.

5. The method of claim 4, wherein the metal contacts are formed to be electrically isolated from each other by the second dielectric.

6. The method of claim 1, wherein forming the corresponding staircase region for each vertical channel structure includes performing at least two etch processes to different depths.

7. The method of claim 1, wherein the vertical channel structures comprise a first field effect transistor and a second field effect transistor on top of the first field effect transistor.

8. The method of claim 7, wherein the first field effect transistor is an n-type transistor structure and the second field effect transistor is a p-type transistor structure.

9. The method of claim 7, wherein the staircase region is a first staircase region for the first field effect transistor, and the method further comprises forming a second staircase region for the second field effect transistor.

10. A method for microfabrication, the method comprising:
forming vertical channel structures on a substrate, the vertical channel structures formed within a layer stack of alternating layers of a first metal and a first dielectric, the vertical channel structures having a current flow path perpendicular to a surface of the substrate, the vertical channel structures having a dielectric core;
forming slot-shaped openings on the substrate that uncover a region of the layer stack adjacent to the vertical channel structures, each slot-shaped opening extending at a particular radial direction from a center point of the vertical channel structures;
for each vertical channel structure, forming a corresponding staircase region in the layer stack in plane with a corresponding vertical channel structure, the staircase region having a staircase profile of metal layers in that each metal layer extending from the corresponding vertical channel structure has a different lateral length for different lateral access from top down access; and
forming metal contacts within staircase region, each metal contact extending from a top surface of the substrate vertically into the staircase region to a corresponding metal line providing electrical connection to a corresponding vertical channel transistor.

11. The method of claim 10, further comprising etching a ring structure around each vertical channel structure stack.

12. The method of claim 10, further comprising forming a second dielectric in the staircase region formed for each vertical channel structure.

13. The method of claim 12, wherein the metal contacts are formed to be electrically isolated from each other by the second dielectric.

14. The method of claim 10, wherein forming the corresponding staircase region for each vertical channel structure includes performing at least two etch processes to different depths.

15. The method of claim 10, wherein the vertical channel structures comprise a first field effect transistor and a second field effect transistor on top of the first field effect transistor.

16. The method of claim 15, wherein the first field effect transistor is an n-type transistor structure and the second field effect transistor is a p-type transistor structure.

17. A device, comprising:
a stack of alternating layers of a metal and a dielectric on a substrate;
a transistor structure in the stack and having a current flow path perpendicular to a surface of the substrate;
a staircase region in the stack of alternating layers in-plane with the transistor structure, the staircase region extending through a plurality of metal layers in the stack that each extend from the transistor structure; and
a respective plurality of metal contacts coupled to the plurality of metal layers exposed in the staircase region, each of the respective plurality of metal contacts extending vertically from a top surface of a respective metal layer of the plurality of metal layers to a corresponding metal line and providing electrical connection to the transistor structure.

18. The device of claim 17, further comprising a second dielectric in the staircase region that isolates the respective plurality of metal contacts are formed to be electrically isolated from each other by the second dielectric.

19. The device of claim 18, further comprising a second staircase region in the stack of alternating layers that is electrically coupled to a second transistor structure.

20. The device of claim 17, further comprising a second dielectric material in the stack that extends vertically from the substrate and isolates the transistor structure from a second transistor structure in the stack.
